(19) United States
(12) Patent Application Publication
(10) Pub. No.: US 2011/0174359 A1
(43) Pub. Date: Jul. 21, 2011

(54) ARRAY MODULE OF PARABOLIC SOLAR ENERGY RECEIVERS

(75) Inventors: ESMOND GOEI, ERIE, CO (US); TAO ZHAO, SINGAPORE (SG); YEN CHIN, SINGAPORE (SG)

(73) Assignee: ASPECT SOLAR PTE LTD., SINGAPORE (SG)

(21) Appl. No.: 13/006,225

(22) Filed: Jan. 13, 2011

Related U.S. Application Data
(60) Provisional application No. 61/295,488, filed on Jan. 15, 2010.
(60) Provisional application No. 61/389,593, filed on Oct. 4, 2010.

(51) Int. Cl. H01L 31/052; H01L 31/00

(52) U.S. Cl. 136/246; 136/259

(57) ABSTRACT

A solar energy receiver array comprises a plurality of solar energy receivers arranged in an X by Y array. A protected housing includes a plurality of sides defining an opening therein. The plurality of solar energy receivers are arranged in the X by Y array may be lowered into the opening within the protective housing to protect the plurality of solar energy receivers arranged in the X by Y array from external winds.

### CROSS-REFERENCE TO RELATED APPLICATIONS

This application claims the benefit of U.S. Provisional Application Ser. No. 61/295,488, filed Jan. 15, 2010, and entitled “SELF-TRACKING ARRAY OF CPV PARABOLIC SOLAR ENERGY RECEIVERS WHICH EMBODIES 3 AXES OF ORIENTATION,” the specification of which is incorporated herein by reference. This application also claims the benefit of U.S. Provisional Application Ser. No. 61/389,593, filed Oct. 4, 2010, and entitled “ARRAY MODULE OF PARABOLIC SOLAR ENERGY RECEIVERS WITH MICRO-POD DEVICE,” the specification of which is incorporated herein by reference. This application is related to U.S. Pat. No. 6,818,818, which issued on Nov. 16, 2004 and is entitled “CONCENTRATING SOLAR ENERGY RECEIVER,” the specification of which is incorporated herein by reference.

### TECHNICAL FIELD

The present invention relates to solar energy conversion, and more particularly, to arrays of self-tracking concentrating solar energy receivers.

### BACKGROUND

Devices for solar energy collection and conversion can be classified into concentrating types and non-concentrating types. Non-concentrating types intercept parallel un-concentrated rays of the sun with an array of detection or receiving devices such as a solar panel of photovoltaic cells or hot water pipes, for example. The output is a direct function of the receiving area of the rays. A concentrating type of solar energy collector focuses the energy rays using, e.g., a parabolic reflector or lens assembly to concentrate the rays, creating a more intense beam of energy. The beam is concentrated to improve the efficiency of conversion of solar radiation to electricity or to increase the amount of heat energy collected from the solar radiation to provide for heating of water and so forth. In a conventional concentrating solar energy receiver, the incident solar radiation is typically focused at a point from a circular reflector (e.g., a dish reflector) or along a focal line from a cylindrical shaped reflector. In another prior art example, a flat portion in the center of a round, parabolic primary reflector provided by flattening the center portion of the reflector radiates to a predetermined diameter before the parabolic curve glances outward to the rim of the reflector. In this device, the reflected solar energy is focused at a ring corresponding to the outer diameter of the flat central portion of the reflector.

However, even conventional concentrating solar energy receivers require improvements for two reasons. First, the solar energy conversion module in conventional systems is located directly at the focal point or focal line which have to deposit a very small volume, this small volume causes a high concentration of heat that must be dissipated in the region of the focal point. Secondly, a large portion of the infrared portion of the radiant solar energy spectrum cannot be efficiently converted to electricity by currently available low mass conversion devices such as solar cells. Instead, this excess infrared energy is collected by the reflector and contributes to heating a conversion device which can impair the conversion efficiency of the solar cells.

Additionally, there is a need to group whichever type of concentrating solar energy receivers are utilized in a configuration array such that the aggregate affect of the energy created by each individual solar energy receiver may be utilized. Alternatively, with array configurations there may be the danger of damages due to external environmental conditions such as high velocity winds. Thus, there is a need for some manner for protecting the solar energy receivers in addition to improving their energy collection and distribution characteristics.

### SUMMARY

The present invention, as disclosed and described herein, in one aspect thereof, comprises a solar energy receiver. The solar energy receiver comprises a plurality of solar energy receivers arranged in an X by Y array. A protective housing includes a plurality of sides defining an opening therein. The plurality of solar energy receivers may be lowered into the opening within the protective housing to protect the plurality of solar energy receivers from external winds.

### BRIEF DESCRIPTION OF THE DRAWINGS

For a more complete understanding, reference is now made to the following description taken in conjunction with the accompanying Drawings in which:

FIG. 1A illustrates one embodiment of a concentrating solar energy receiver;

FIG. 1B illustrates an alternative embodiment of the concentrating solar energy receiver having both a primary reflector and a secondary reflector;

FIG. 2A is a pictorial drawing of the embodiment of FIG. 1A showing the supporting structure for the primary reflector and a corresponding solar to electrical energy conversion module;

FIG. 2B is a pictorial drawing illustrating an alternative embodiment of FIG. 1B showing the supporting structure for the primary and secondary reflectors and the corresponding solar to electrical energy conversion modules;

FIG. 3 illustrates another alternative embodiment of the concentrating solar energy receiver of FIG. 1A wherein the focal area is positioned away from the principal axis of the primary reflector;

FIG. 4 is a graph illustrating the various components and wavelengths of the solar radiation spectrum as compared with the effects of the atmosphere thereon in the conversion and path of several currently available solar energy conversion devices;

FIG. 5 is a graph showing the typical relative quantum efficiency versus the active wavelength range of a triple junction GaInP₂/GaAs/Ge solar cell;

FIG. 6 is a graph showing the typical conversion efficiency performance versus the solar energy radiation level for a triple junction solar cell as shown in FIG. 5;

FIG. 7A illustrates a design example for a concentrating solar energy receiver according to the present disclosure;

FIG. 7B illustrates an alternative embodiment of FIG. 2A using a film recycle engine in a solar to electrical energy conversion module;

FIG. 8 illustrates a solar energy receiver pod;

FIG. 9 illustrates a transparent cover of a solar energy receiver pod including an integrated secondary reflector;

FIG. 10 illustrates a side view of an integrated primary reflector and heat sink of a solar energy receiver pod;

FIG. 11 illustrates a ganged array of solar energy receiver pods utilizing a single common sun tracking mechanism;

FIGS. 12A-12D illustrates the array of solar energy receiver pods within various positions;

FIG. 13 is a functional block diagram illustrating the connection of multiple solar energy receiver modules to a power grid and centralized controller;

FIG. 14 illustrates a further embodiment of a solar energy receiver module;

FIG. 15 illustrates a side view of a self-tracking solar energy receiver (“pod”) rotatable about three different axis;

FIG. 16 illustrates a two axis implementation of a solar energy receiver using a parabolic dish;

FIG. 17 illustrates an implementation of a solar energy receiver using a Fresnal lens;

FIGS. 18A-C illustrate a solar energy receiver controlled via a tracking algorithm;

FIG. 19 is a flow diagram describing one possible control algorithm for positioning a solar energy receiver;

FIG. 20 illustrates a solar energy receiver including light sensors for providing a self-tracking ability;

FIG. 21 illustrates a block diagram of a control mechanism for controlling tracking of a solar energy receiver via light sensors;

FIG. 22 is a flow diagram illustrating a control method for a solar energy receiver using light sensors;

FIG. 23 is a flow diagram describing a method for accounting for misalignment within a tracking algorithm; and

FIG. 24 illustrates an array of solar energy receivers communicating via wireless communications.

### DETAILED DESCRIPTION

Referring now to the drawings, wherein like reference numbers are used herein to designate like elements throughout, the various views and embodiments of an array module of parabolic solar energy receivers are illustrated and described, and other possible embodiments are described. The figures are not necessarily drawn to scale, and in some instances the drawings have been exaggerated and/or simplified in places for illustrative purposes only. One of ordinary skill in the art will appreciate the many possible applications and variations based on the following examples of possible embodiments.

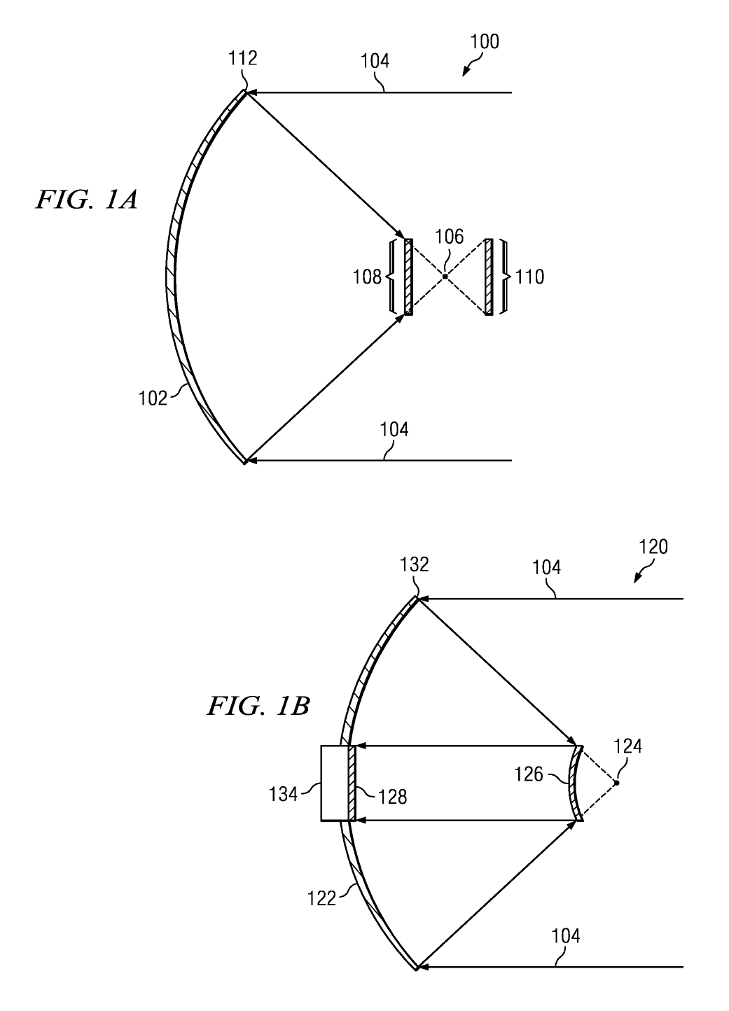

Referring now to FIG. 1A, there is illustrated one embodiment of a concentrating solar energy receiver according to the present disclosure. The concentrating solar energy receiver 100 includes a primary parabolic reflector 102 shown in cross-section, which intercepts solar energy radiation in the form of a plurality of incident rays 104 being reflected from a highly reflective concave side of the primary parabolic reflector 102 toward a focal point 106. It will be appreciated that the focal point 106 lies along the first or principle focal axis of the primary parabolic reflector 102 and passes through the center of the reflector 102 and substantially perpendicular to a plane tangent to the center of the reflector 102. This focal axis is not shown in the diagram for clarity, but will be understood to be present as described unless otherwise stated. As is well-known, incident rays 104 from the sun falling within the outer rim 112 of the primary parabolic reflector 102 will be reflected through the focal point 106. Also shown in FIG. 1A are a near focal area 108 and a far focal area 110. These focal areas, which each define a planar region disposed substantially at right angles to the principle focal axis passing through the focal point 106, are offset or displaced along the principle axis by a predetermined distance either toward the primary parabolic reflector 102 or away from the primary parabolic reflector 102. The area of a focal area is approximately the same, or slightly larger than, the cross-sectional area of the reflected radiation pattern at the location of the focal plane along the principle axis.

A focal area in this disclosure is defined as a planar region representing the desired position of a sensor for receiving solar energy for the purpose of converting it to another form. Such focal area regions may also be referred to herein as reception areas or reception surfaces. Reception or solar sensor surfaces are the energy-incident portions of a conversion device or module which receive the incident energy and transfer it to structures in the conversion device or module which convert the incident solar energy to an electrical, mechanical or thermal form. It will be readily appreciated by those skilled in the art that a solar energy sensor having a plane area approximately the size of focal area 108, or alternatively, focal area 110, is in a position to intercept all of the reflected incident rays being directed through the focal point 106. In addition, the reflected solar energy is uniformly distributed at a lower average intensity throughout that focal area. Thus, the solar energy sensor located at a focal area intercepts all of the radiation but intercepts the energy at a uniform, lower intensity which, in practical terms, means that the solar energy sensor is less subject to intensity peaks and can more readily dissipate heat energy that is outside the conversion bandpass of the conversion module. This is because the heat energy contained in the solar radiation is intercepted over a larger area than would exist at the more concentrated focal point. By distributing the received energy evenly over a larger surface, the useful operating life of the conversion module is increased significantly. Thus, a concentrating solar energy receiver configured as shown in FIG. 1A can be built in a wider variety of sizes with much less severe constraints placed upon the heat dissipation capability of the solar energy conversion module that is utilized in the concentrating solar energy receiver of the present disclosure. It will be apparent from the description which follows that some of the parameters which may be adjusted to provide various output levels are the size of the primary reflector, the size of the solar sensor, the position or offset of the solar sensor from the focal point, the way in which heat dissipation is provided, etc.

Continuing with FIG. 1A, the primary parabolic reflector 102 shown in FIG. 1A in cross section may in general be of circular shape, that is, the rim 112 when viewed looking toward the concave surface of the primary parabolic reflector 102 appears as a circle. As is well known, this is an efficient shape for receiving incident solar energy radiation. However, the concentrating solar energy receiver 100 of the present disclosure is not limited to a circular primary reflector 102 but could be other geometric shapes such as an ellipse, an oval, a rectangle (i.e., a cylindrical reflector), a polygon or an array of regular polygons or any other closed plane figure with a parabolic surface. Such an array of panel segments could be a composite of contiguous shapes placed edge-to edge or a composite of reflecting elements arranged in proximity to one another or a composite of reflecting elements arranged in predetermined positions though not necessarily close together. Further, the individual panel segments may have a flat or curved surface. The primary reflector may be constructed of any material in which the desired parabolic shape may be maintained. Some examples of suitable materials include metals, such as polished aluminum, steel with nickel or chromium plating; glass, with or without a silvered coating (as in a mirror); ceramics or other composites such as fiberglass, graphite, polymers or plastics having a reflective coating or plating; or any other material that meets the structural and reflective properties required of a parabolic reflector. In some applications, a reflective sheet or membrane having sufficient support to maintain a parabolic shape may be used as a reflector. However, it will be appreciated by persons skilled in the art that a lightweight metal such as aluminum offers a number of advantages such as high strength-to-weight ratio, ease of manufacture, ability to provide a polished, highly reflective finish and the ability to conduct heat away from any structure that is mounted thereon. Some of the various construction variations will be described in detail hereinbelow.

Continuing with FIG. 1A, the solar energy conversion module, which may be used with the primary parabolic reflector 102 and which has a planar solar energy sensor to be positioned within one or the other of the focal areas 108, 110, may be of several basic types. These may include, illustratively, an array of one or more photovoltaic solar cells or a thermal cycle engine coupled to an electric generator, for example. In this description, an electric generator may refer to any device which converts solar or mechanical or thermal energy to direct or alternating current electricity. Further, an electric generator includes an alternator. The specific solar energy conversion module that may be used in the embodiment of FIG. 1A is not shown therein for clarity, the purpose of FIG. 1A being to illustrate the principle of positioning the solar sensor portion of the conversion module at a predetermined distance from the actual focal point of the primary parabolic reflector 102. As will become apparent hereinbelow, the choice of which focal area 108 or 110 is selected for a particular application will become clear as various embodiments of the concentrating solar energy receiver 100 are further described.

In a preferred embodiment of the concentrating solar energy receiver shown in FIG. 1A, a photovoltaic solar cell conversion module includes one or more triple junction solar cells, specifically triple junction GaInP₂/GaAs/Ge solar cells. Such solar cells currently available are capable of operating with intensities of solar radiation of up to several hundred suns, where one sun equals 0.1368 watts per centimeter squared (W/cm²). Solar cells suitable for use in the concentrating solar energy receiver of the present disclosure include devices manufactured by EMCORE Photovoltaics of Albuquerque, N. Mex. or Spectrolab, Inc., a division of the Boeing Company located in Sylmar, Calif. The solar energy sensor for a conversion device will typically be made up of an array of solar cells of the type described in the foregoing, arranged in a planar array to be positioned in the plane of the focal area chosen. It is essential to ensure that the solar sensor be carefully positioned so that the sunlight reflected from the primary reflector is uniformly distributed throughout the focal area and is uniformly distributed upon the surface of the solar cell array. Failure to ensure a uniform distribution of reflected energy can result in damage to the conversion module.

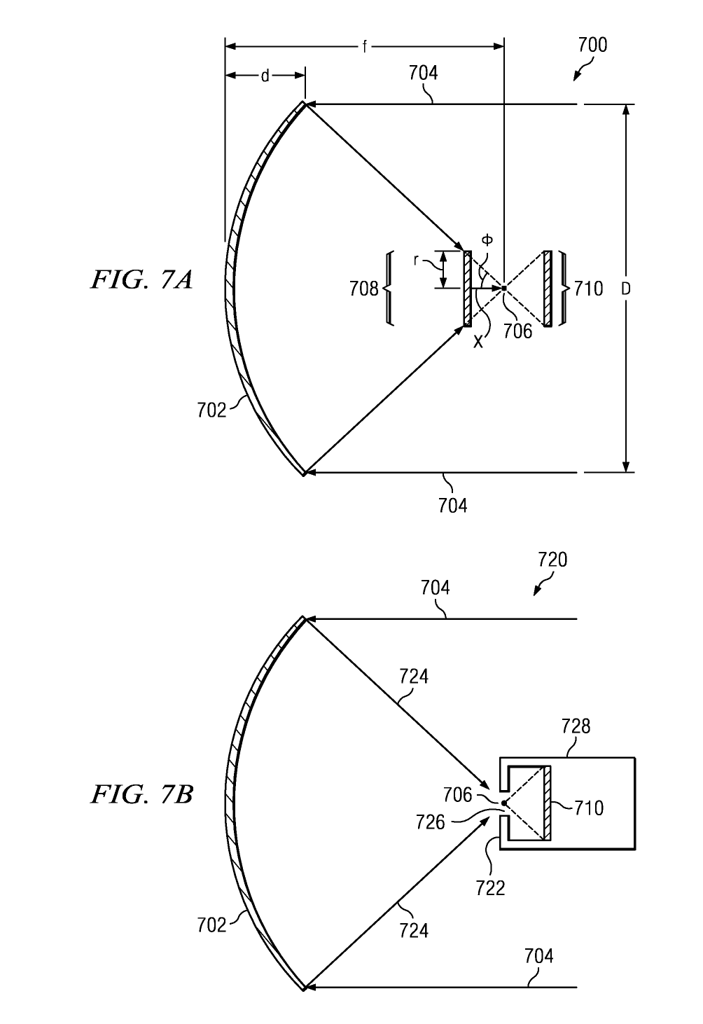

Generally speaking, the focal area 108 is preferred for the location of the solar sensor of the conversion module. However, the focal area 110 is preferable when a thermal cycle engine is selected as the conversion device because that location enables the conversion device, that is the thermal cycle engine, to be fully enclosed within a housing having an aperture positioned to surround the focal point 106. This configuration, which is illustrated in FIG. 7B, permits the entry of all of the reflected incident rays into the housing surrounding the thermal cycle engine. This housing may be fully insulated and configured to contain any heat energy that might otherwise escape from the heat engine to the surroundings. Thus, the amount of heat energy presented to the input of the thermal cycle engine may be maximized for optimum efficiency of the concentrating solar energy receiver that employs a thermal cycle engine. In applications where it is desired to utilize a thermal cycle engine, one suitable choice is a Stirling engine which, as is well known in the art, is a closed cycle regenerative heat engine which alternately stores energy in a working fluid. In another portion of the cycle the energy is released from the working fluid as the heat input to the thermal cycle engine is converted to mechanical motion—e.g., rotary or reciprocating—and used to drive a generator to produce electricity. Stirling engines may be readily built using construction information that is widely available and so will not be described further herein.

Referring now to FIG. 1B, there is illustrated an alternate embodiment of a concentrating solar energy receiver 120 showing, in cross section, a primary parabolic reflector 122 which intercepts the incident rays of solar radiation 104 falling within the outer rim 132 and reflects them toward a focal point 124 which is located on a principle axis passing through the center of the primary parabolic reflector 122. In FIG. 1B, the principle axis passing through the center of the primary reflector 122 is not shown for clarity, it being understood where it is located. The characteristics of the primary parabolic reflector 122 are the same as described for the primary parabolic reflector 102 of FIG. 1A. A focal area is also defined for the embodiment shown in FIG. 1B. However, in the focal area 126 of FIG. 1B, there is positioned a secondary parabolic reflector 126, which has characteristics (except for size) generally to same as or similar to the primary parabolic reflector 122. The secondary parabolic reflector 126 may be constructed in the same way as the primary parabolic reflector 122. In this embodiment, the secondary parabolic reflector is disposed to intercept and reflect all incident rays 104 reflected from the primary parabolic reflector 122 from a convex surface of the secondary parabolic reflector 126 back toward the central portion of the primary parabolic reflector 122. As will be appreciated, the convex parabolic surface of the secondary parabolic reflector 126 enables the reflection of the rays incident thereon in a direction that is parallel to the original incoming incident rays 104 from the sun. Thus, the rays reflected from the secondary parabolic reflector are substantially parallel and will illuminate the center portion of the primary parabolic reflector. This centrally-located focal area, now defined in the center of the primary parabolic reflector, may also be called a reception surface 128. The reception surface 128 is part of a conversion module 134. The secondary parabolic reflector 126 is offset by a predetermined distance from the focal point 124 toward the primary parabolic reflector 122. Again, to control the cross-sectional area of the incident solar radiation beam so as to correspond with the overall cross-sectional area of the solar sensor utilized in a conversion module, the reception area is sized and placed so that the solar sensor region is substantially in the plane of the primary parabolic reflector. This embodiment presents several advantages for maximizing the efficiency of a concentrating solar energy receiver according to the present disclosure as will be described more fully hereinbelow.

Continuing with FIG. 1B, the concentrating solar energy receiver 120 shown therein has three advantages over the embodiment illustrated in FIG. 1A. First, locating the focal area 128, or alternatively the reception surface 128, at the central portion of the primary parabolic reflector 122 permits the conversion module 134 to transfer excess heat produced by the incident radiation within the heat dissipating qualities of the material used for the primary parabolic reflector 122. Thus, for example, if the primary reflector is constructed of aluminum and the conversion module having a solar sensor in the plane of the central portion of the primary reflector 122, is placed in contact with the primary reflector 122 it may transfer the heat from the conversion module 134 to the metal shell forming the primary reflector 122.

Second, by locating the conversion module 134 at the center part of the primary reflector 122, the center of gravity of the entire concentrating solar energy receiver may be more closely positioned to the supporting structure of the primary parabolic reflector 122. Thus, the largest single unit of the concentrating solar energy receiver 120 in combination with the conversion module 134 permits smaller and more efficient structures for moving and positioning the assembly with respect to the direction of the sun, etc.

Third, the positioning of a secondary reflector at the focal area 126 not only facilitates the two advantages described above, but it also permits the use of a filter element (not shown in FIG. 1B) to be placed on or in front of the secondary parabolic reflector 126 for the purpose of filtering solar radiation components which lie outside the conversion bandpass of the solar sensor and conversion module 134 that is utilized for the concentrating solar energy receiver 120. For example, a filtering material can be laminated or attached to the secondary parabolic reflector 126 to permit only solar energy which is within the conversion bandpass of the solar sensor and conversion module 134, thus limiting the amount of unconvertible energy reaching the surface of the solar sensor portion of the conversion module 134 and reducing thereby the heat dissipation requirements of the conversion module 134 itself. To say it another way, the use of a filter in conjunction with the secondary parabolic reflector 126 controls the admittance bandpass of the concentrating solar energy receiver so that it corresponds substantially to the conversion bandpass of the solar energy conversion module 134 that is utilized with the concentrating solar energy receiver 120 of FIG. 1B.

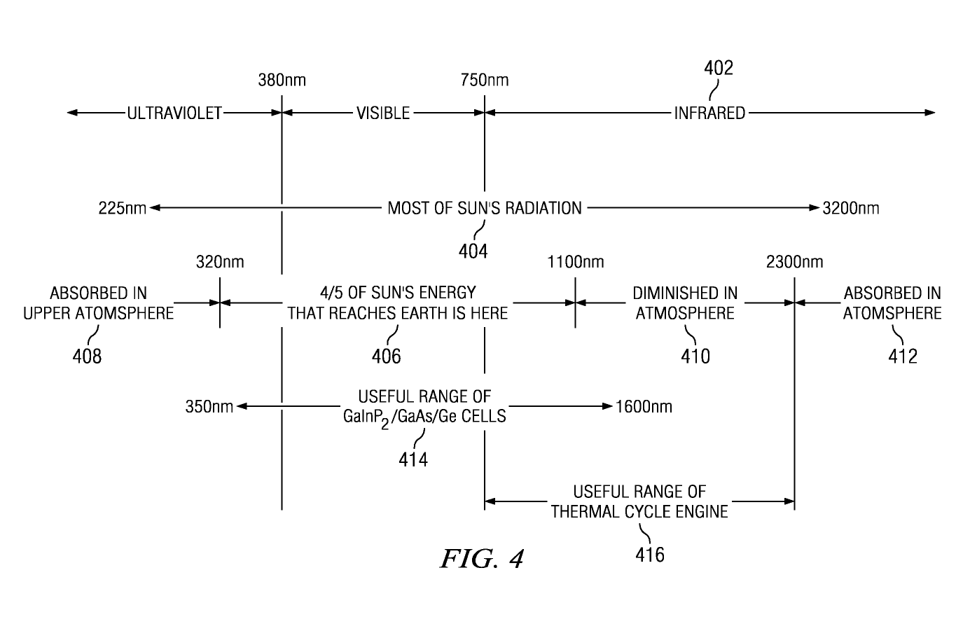

Continuing further with FIG. 1B, the reflective properties of the secondary parabolic reflector 126 may be altered in a number of ways to provide the filtering effect described hereinabove. For example, a number of processes in manufacturing are suitable. These may include laminating or applying a chemical coating or covering or depositing a film of suitable material on the surface of the secondary parabolic reflector 126. The use of a specialized material positioned next to the surface of the secondary reflector itself may also be utilized to provide the required filtering. Other processes useable to achieve the desired reflective properties may include chemical plating or doping of the reflector surface material and the like. In one alternative embodiment a secondary parabolic reflector may be may of a glass or plastic material that is transparent to some wavelengths of solar radiation (which are not useful for conversion by present conversion devices) and reflective to other wavelengths which are useful for conversion of solar energy to electrical energy or to other useful forms. As an example, glass is a versatile material that may be coated to provide a variety of properties including reflection, absorption or filtering of specified wavelengths. The techniques and processes for achieving such properties are well known and will not be further described herein. Excess energy in the form of spectral solar radiation components that are not needed by the conversion device may be absorbed, passed-through or dissipated over the surface area of the secondary parabolic reflector 126 and radiated to the environment through a suitable heat sinking or conducted to a heat exchanger configured for the purpose. It will also be appreciated that a filter element may be used with, applied to or incorporated with the primary parabolic reflector, either to supplement the filtering associated with the secondary parabolic reflector or in the embodiment wherein a secondary parabolic reflector is not used. Such a primary parabolic reflector could be constructed as outlined previously in this paragraph. Details of the solar energy radiation spectrum and the bandpass aspects of various structures of the concentrating solar energy receiver of the present disclosure will be described further in conjunction with FIGS. 4, 5 and 6.

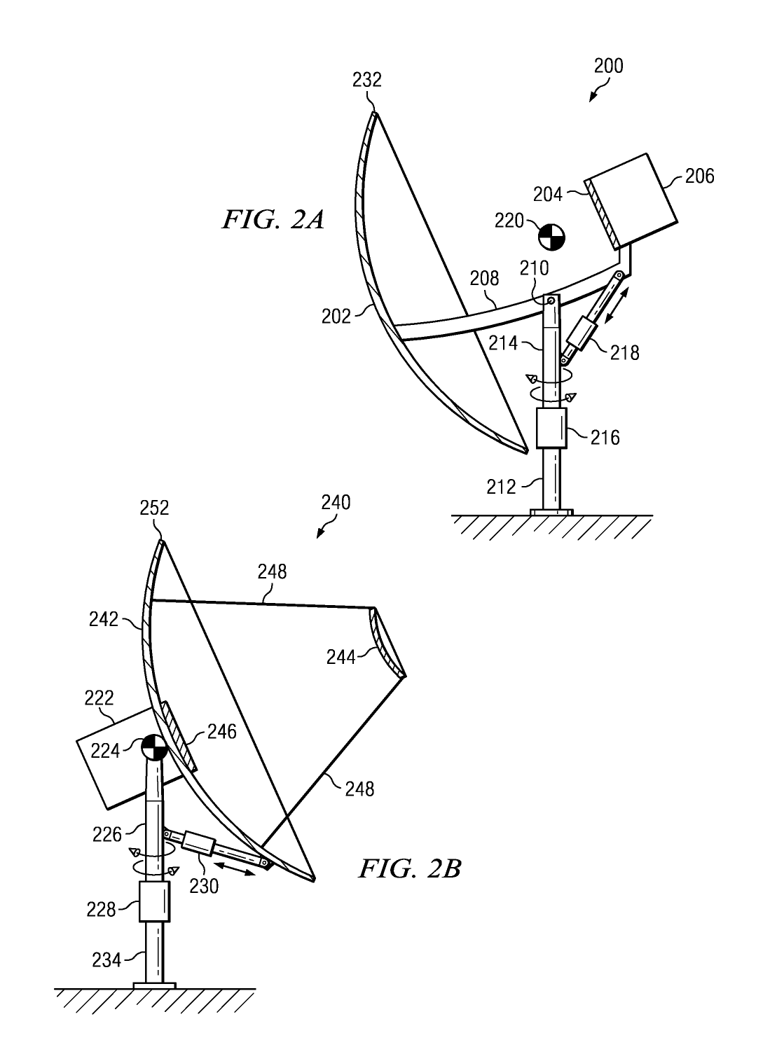

Referring now to FIG. 2A, there is illustrated an embodiment of a concentrating solar energy receiver shown in pictorial form to illustrate a mounting structure for a concentrating solar energy receiver according to the present disclosure. The concentrating solar energy receiver 200 of FIG. 2A includes a primary parabolic reflector 202 shown in cross section and having a circular shape and a rim 232 which defines the circular outer perimeter of the primary parabolic reflector 202. Also shown in FIG. 2A is a focal area 204 (or reception surface 204) which represents the solar sensing surface of a conversion module 206. The primary parabolic reflector 202 is as previously described in conjunction with FIG. 1A. The focal area 204 is as previously described in FIG. 1A wherein the focal area 204 is offset with respect to the focal point of the primary parabolic reflector as the near focal area 108 appears in FIG. 1A. In FIG. 2A, the focal area 204 represents the solar sensing portion of a conversion module 206. The conversion module 206 may illustratively be a solar cell array as previously described hereinabove or it may also be a combination of a thermal cycle engine and an electric generator unit as also previously described.

Continuing with FIG. 2A, the primary parabolic reflector 202 and the conversion module 206, which includes the reception surface 204, are held in a fixed relationship by a first frame member 208. The first frame member 208 is connected to the primary parabolic reflector 202 near its center and extends therefrom to connect with and support the conversion module 206 along the principle axis of the primary parabolic reflector 202. The solar sensor in the reception surface 204 is thus positioned to directly face the center portion of the primary parabolic reflector 202 such that it receives all of the solar energy radiation being reflected from the primary parabolic reflector 202. The first frame member 208 is connected to a rotatable vertical post 214 at a pivoting joint 210 which permits the first frame member 208 to rock in a vertical plane about a horizontal axis so that the primary parabolic reflector 202 may be positioned at any required elevation angle while pivoting about the axis of the pivoting joint 210. The rocking motion of the first frame member 208 is provided by a vertical control actuator 218 which consists of a variable length strut whose length may be varied under the action of a motor or linear actuator in the longitudinal axis of the vertical control actuator 218. The rotating post 214 is rotatably secured to a horizontal control motor 216 which in turn is supported by a vertically oriented stationary base 212 anchored upon the ground, a building or other structure. The vertical control actuator 218 provides for adjusting the elevation of the concentrating solar energy receiver assembly 200 of the present disclosure. The horizontal control motor permits the adjustment of the azimuth of the concentrating solar energy conversion receiver 200 of the present disclosure. Thus the primary parabolic reflector 202 of a concentrating solar energy receiver 200 may be aimed directly at the sun and enabled to track the sun as it proceeds across the sky during daylight hours.

One property of the concentrating solar energy receiver 200 illustrated in FIG. 2A is that the center of gravity 220 of the movable portion of the system is located approximately between the primary parabolic reflector 202 and the conversion module 206 near the principle axis of the primary parabolic reflector 202 and approximately above the upward end of the rotating vertical post 214 coupled to the first frame supporting member 208. The embodiment of FIG. 2A would be suitable for use with the solar cell type of conversion module with the solar sensing portion positioned in the region of the near focal area as shown in the near focal area 108 of FIG. 1A. However, the embodiment of FIG. 2A may also be adapted to use with a thermal cycle engine type of conversion module by locating the solar sensing portion of the thermal cycle engine in the region of the far focal area 110 of FIG. 1A. In this position, the conversion module 206 that utilizes a thermal cycle engine can be enclosed in a housing having an aperture located surrounding the focal point (see, e.g., FIG. 7B), the housing being utilized to contain the heat energy within a near field of the solar energy portion of the thermal cycle engine to maximize the amount of heat applied to the input of the thermal cycle engine.

Continuing with FIG. 2A, while the embodiment illustrated therein applies one of the principles of the present disclosure, that is in utilizing an offset focal area, this embodiment is somewhat awkward mechanically. It is more expensive and less efficient to implement because of the attachment of the first frame member 208 to the concave side of the primary reflector 202 and because of the location of the center of gravity 220 away from the structures of the concentrating solar energy receiver 200 having the most mass. For example, in order for the primary reflector 202 to be aimed at the sun when the sun is directly overhead, a large cut-out region or slot must be cut into the primary reflector 202 to permit it to move past the base 212, vertical support 214 and control motor 216. Further, a greater amount of structural components are required to support the primary reflector 202 and the conversion module 206 in the correct relationship as shown in FIG. 2A. The cutout region in the primary reflector 202 creates additional complexity in the mechanical support to maintain the parabolic shape of the primary reflector 202 as well as reduces the available reflective surface area for use in receiving sunlight.

Referring now to FIG. 2B, there is illustrated an alternate and preferred embodiment of a concentrating solar energy receiver 240 according to the principles of the present disclosure. In this embodiment, the primary parabolic reflector 242, shown in cross section and having a circular rim 252 includes a secondary parabolic reflector 244 disposed along the principle focal axis of the primary reflector and at the near focal area for reflecting radiant energy toward a focal area 246 (or reception surface 246) on the surface of the center portion of the primary parabolic reflector 242. Also located in the center portion of the primary parabolic reflector 242 is the conversion module 222 which includes the solar sensing reception surface 246 mounted in the center portion of the primary parabolic reflector 242. The secondary parabolic reflector 244 is shown supported on struts 248 which may be attached to the rim 252 or, as shown in FIG. 2B, to the concave side of the primary parabolic reflector 242. It will be appreciated that the focal axis of the secondary reflector 244 lies along the focal axis of the primary reflector in the embodiment of FIG. 2B, that is, their principle axes are coincident.

With the distribution of masses of the various components of the concentrating solar energy receiver 240 as shown in FIG. 2B, the center of gravity is located approximately at the center of and just behind the primary parabolic reflector 242. This location of the center of gravity 224 considerably simplifies the supporting structure needed to support the concentrating solar energy receiver 240 and provide for its movement in both the elevation and azimuth directions. The concentrating solar energy receiver 240 is supported at the top of a rotating vertical post 226. Rotating vertical post 226 is controlled by a horizontal control motor 228 which is supported at the upper end of a vertically oriented stationary base 234. The stationary base 234 may be mounted upon the ground, a building or other structure. Also attached to the rotating vertical post 226 is a vertical control motor 230, which is a variable length strut controlled by a linear actuator or motor disposed along the longitudinal axis of the variable length strut and is provided to control the elevation of the concentrating solar energy receiver 240. The azimuth orientation of the concentrating solar energy receiver 240 is controlled by the horizontal control motor 228. It will be appreciated that in both FIGS. 2A and 2B, the respective control motors for the vertical (elevation) and horizontal (azimuth) may be controlled by suitable electronics which are not shown in the diagrams, but are readily available and known to persons skilled in the art.

Continuing with FIG. 2B, it is apparent that locating the most massive components together positions the center of gravity in such away that the responsiveness of the control system is maximized and the size of the actuating units and motors is minimized, thus increasing performance and reducing the cost of the assemblies required. Further, the use of the secondary parabolic reflector 244 more readily permits the use of filtering elements as described hereinabove so that the admittance bandpass of the reflecting portions of the concentrating solar energy receiver 240 is well matched to the conversion bandpass of the conversion module 222 utilized therein. This advantage is especially realized when the conversion module 222 employs a solar cell array of the triple junction solar cells previously described. Matching of the light reflecting filtering and absorption properties of the secondary reflector 244 can be accomplished using any of several processes in manufacturing including, but not limited to, chemical coating or plating or deposition of other materials on the surface of the secondary parabolic reflector 244, or use of specialized materials in the reflector construction, or the use of chemical doping of the reflective material, or lamination of filtering materials upon the reflective surface of the secondary parabolic reflector 244. Excess heat which is rejected by the filtering element or otherwise absorbed by the secondary parabolic reflector 244 may be dissipated over the surface area of the secondary parabolic reflector 244. Further, the secondary reflector may be mounted on a heat sink structure to improve the dissipation of heat therefrom. Alternatively a filtering element or function may be applied to the primary parabolic reflector 242 or to the reception surface 246, with excess heat energy dissipated through contact with adjacent structures in the primary parabolic reflector 242. In typical applications, filtering maybe applied to one or more of the three structures: the primary reflector 242, secondary reflector 244 and the reception surface 246. In an alternate embodiment the secondary parabolic reflector may be fabricated of glass or other similar transmissive material that reflects wavelengths to be applied to the solar energy reception surface and passes through those wavelengths which will not be received and utilized.

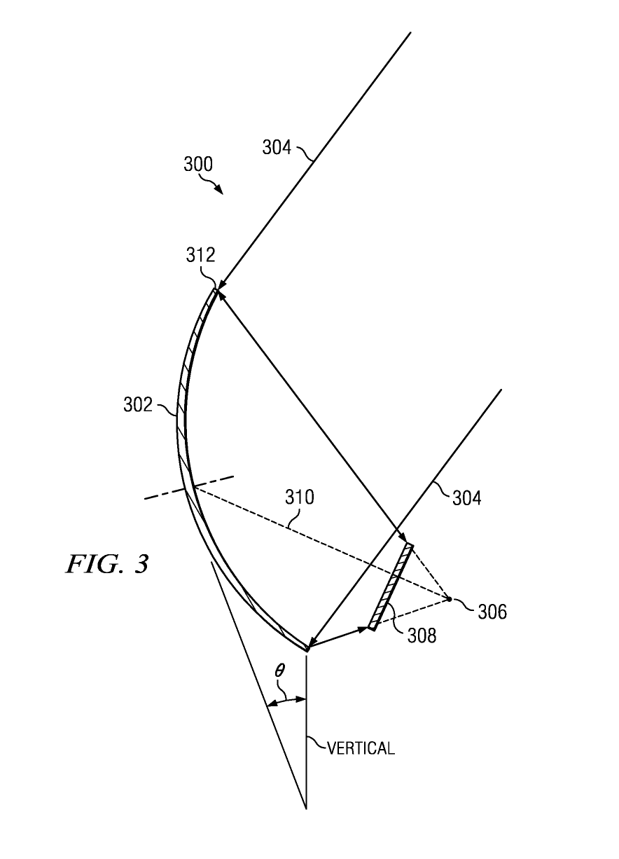

Referring now to FIG. 3, there is illustrated an alternate embodiment of the concentrating solar energy receiver of the present disclosure. It will be recalled from the description of FIGS. 1A, 1B, 2A and 2B that the focal areas or solar sensors or solar cells or secondary reflectors have been located on the principle axis of the primary reflector. These embodiments are known as prime focus reflectors because of the location of the sensing or reflecting elements along the principle axis of the primary reflector. An alternate embodiment as shown in FIG. 3 offsets the focal point from the principle axis in order to maintain the primary reflector 302 at a steeper angle θ with respect to the earth's surface. This orientation prevents the accumulation of debris and other precipitants or particulates. It also allows moisture and contaminants to drain from the reflective surface while the primary reflector 302 is collecting incident solar radiation from relatively high elevation angles. The primary parabolic reflector 302 of FIG. 3 is also shown in cross section and in a shape having a rim 312. Solar radiation along incident rays 304 is reflected toward the focal point 306 located along an offset focal axis which also passes through the center of the primary parabolic reflector 302. As before, the focal area 308, which represents the potential position of the solar sensor portion of a conversion module or secondary reflector, may typically be oriented perpendicular to the focal axis 310, but may in some applications be oriented at angles other than perpendicular to the focal axis 310. However, in the embodiment shown in FIG. 3 the solar sensor is shown positioned at the near focal area 308 and approximately perpendicular to the focal axis 310. As thus positioned, the primary parabolic reflector 302 will tend not to accumulate atmospheric precipitation such as rain, snow or other contaminants (such as dust or other particulates) all of which may damage the reflector or tend to reduce the operating efficiency of the concentrating solar energy receiver of the present disclosure. The principle components of the concentrating solar energy receiver 300 as shown in FIG. 3 may be supported by similar structures as described previously in conjunction with FIGS. 2A and 2B.

Referring now to FIG. 4, there is shown a series of graphs representing the spectrum components of electromagnetic radiation along axis 402. These categories include wavelengths shorter than 380 nanometers, the ultraviolet spectrum, between 380 nanometers and 750 nanometers, the visible light spectrum, and for wavelengths longer than 750 nanometers, the infrared radiation spectrum. On another axis 404 is represented the range of solar radiation extending from 225 nanometers to 3200 nanometers which overlaps the three categories of electromagnetic radiation described above. On a third axis is represented the destination of the solar radiation as it travels from the sun toward the earth. The range of 320 nanometers to 1100 nanometers along axis 406, which straddles the visible light spectrum as well as a portion of the ultraviolet and infrared spectrums, includes approximately ⅘ of the sun's energy that reaches the earth Ultraviolet wavelengths shorter than 320 nanometers are absorbed in the upper atmosphere as represented on axis 408. For infrared wavelengths longer than 1100 nanometers, axis 410 shows that this energy is diminished or attenuated as it passes through the earth's atmosphere. The very long infrared wavelengths greater than 2300 nanometers in length are absorbed in the atmosphere as represented along axis 412 and do not reach the surface of the earth.

Continuing with FIG. 4, an axis 414 represents the useful range or conversion bandpass of the triple junction solar cells contemplated for application in several of the embodiments of the present disclosure. This conversion bandpass of the triple junction GaInP₂/GaAs/Ge solar cells extends from 350 nanometers in the near ultraviolet spectrum through the visible light spectrum to the near infrared spectrum at approximately of 1600 nanometers. As can be seen from FIG. 4, this conversion bandpass covers essentially the entire range wherein ⅘ of sun's energy reaches the earth's surface. Thus, a conversion module which uses a triple junction solar cell as described herein is able to capture approximately ⅘ of the radiation from the sun for conversion to electricity or other uses. Also shown in FIG. 4 is the approximate useful range of a typical thermal cycle engine which is shown along line 416 to extend from approximately 750 nanometers through the infrared spectrum range to at least 2300 nanometers. It will be appreciated that the solar energy reaching the surface of the earth lies between the wavelengths of 320 nanometers and 2300 nanometers and is greater than the range of wavelengths of conversion of the presently available triple junction cells employed in the preferred embodiments. It may also be appreciated that, wide as the conversion bandpass of presently available triple junction solar cells is, further advances in technology may extend this range beyond the present limits so that conversion of energy in the wavelengths shorter than approximately 350 nm and/or longer than approximately 1600 nm would permit useful conversion applications in locations at the earth's surface or above the earth's atmosphere such as in space stations, satellites and the like.

The energy of the spectrum which lies outside the range of the triple junction cells, that is, having wavelengths smaller than 350 nanometers or greater than 1600 nanometers, represents unuseable or excess energy. This excess energy may cause a decrease in the efficiency of the triple junction cells and thus represents energy that must be reduced, diverted or otherwise dissipated. As described previously hereinabove, one way to reduce this excess energy is to filter it. For example, a filter element may be used in conjunction with a secondary parabolic reflector. The filter element may be a coating applied to the surface of the reflector or it may be an integral property of the reflector as described hereinabove. Filtering may also be applied at the primary parabolic reflector or disposed as a separate element of the concentrating solar energy receiver disclosed herein.

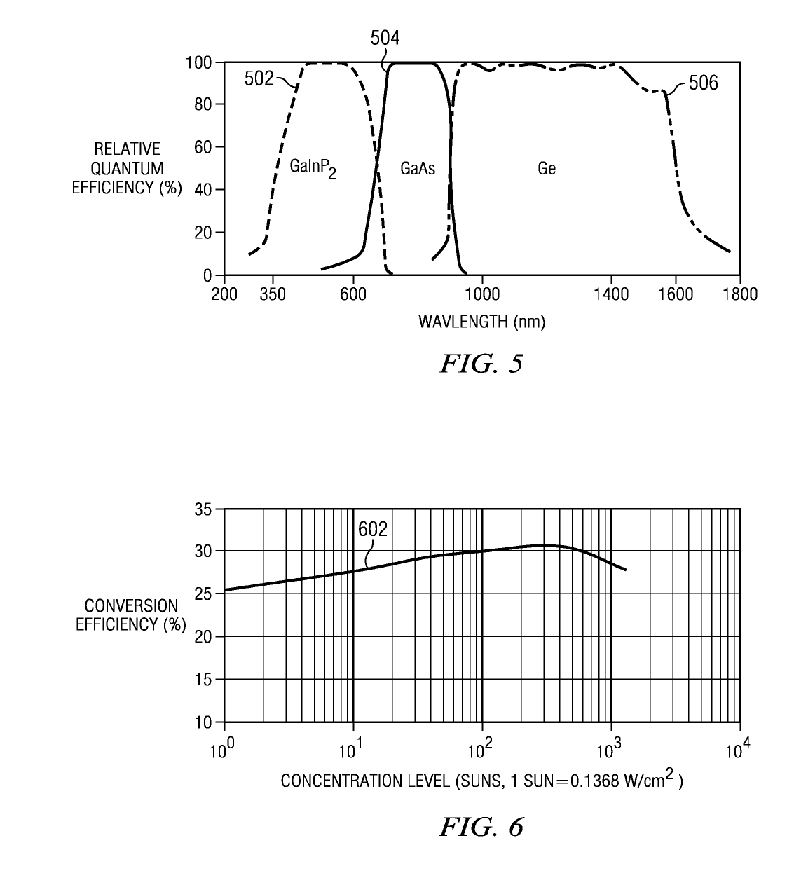

Referring now to FIG. 5, there is illustrated a graph of the relative quantum efficiency in percent versus the wavelength in nanometers of the distinct semiconductor portions of the triple junction solar cell suggested for use in the preferred embodiments of the present disclosure. The three semiconductor materials include a compound of gallium, indium and phosphorous, designated as GaInP₂, gallium arsenide, designated by GaAs and the element germanium, Ge. The useful relative quantum efficiency range of the gallium indium phosphorous compound shown by the dashed line 502 extends approximately from 350 to 650 nanometers. The useful relative quantum efficiency range of the gallium arsenide semiconductor material extends from approximately 650 nanometers to approximately 900 nanometers as shown by the solid line 504. The useful relative quantum efficiency range of the germanium semiconductor material, as shown by the dotted line 506, extends from approximately 900 nanometers to approximately 1600 nanometers. Thus, it can be seen that the approximate composite conversion bandwidth for the triple junction solar cell described in FIG. 5 extends from approximately 350 nanometers to 1600 nanometers which is in agreement with the illustration in FIG. 4.

Referring now to FIG. 6, there is illustrated a graph of the overall conversion efficiency of the triple junction solar cells described hereinabove in percent versus the concentration level of the solar radiation in units of suns, wherein one sun equals 0.1368 watts per centimeter squared (W/cm²). This level corresponds to the intensity of the direct solar energy radiation at the earth's surface of approximately 1 kW/m². It can be seen from the solid line 602 in the graph of FIG. 6 that the conversion efficiency of the triple junction solar cells covers a broad range of solar energy concentration level exceeding 25% from a concentration level of one sun to greater than 1000 suns with the peak occurring between approximately 100 and 600 suns.

Referring now to FIG. 7A, there is illustrated a cross sectional view of a concentrating solar energy receiver 702 similar to that illustrated in FIG. 1A. Some of the calculations for designing a typical concentrating solar energy receiver of the present disclosure will now be described. A primary parabolic reflector 702 is shown in cross section which reflects incident rays 704 to focal point 706. These reflected rays may pass through either near focal area 708 or far focal area 710. Also shown in FIG. 7A are symbols representing various dimensions which will be used in the calculations. The symbol D represents the aperture or diameter of the primary parabolic reflector. The symbol d represents the depth of a primary parabolic reflector. The symbol f represents the distance from the primary parabolic reflector center to the focal point along a principle axis. A symbol r represents of the radius of the circular focal area. It will be appreciated that, as this embodiment is shown in cross-section, both the primary parabolic reflector and the focal area will be circular shapes as previously described hereinabove. The symbol x represents the distance from the focal point to the focal area in either direction along the principle axis. The variables r and x are related by the equation:

Further, the “shallowness” of a parabolic reflector is given by the ratio f/D. In practice, this ratio would need to be between approximately 0.25 and 1.0 in order to preserve the ease of manufacturing. Moreover, as a practical matter, it is much easier to fabricate, finish, and transport shallow (that is, low f/D ratio) prime focus parabolic reflectors. The radius r is determined from the amount of surface area of the reception area part of the conversion module i.e., the diameter of the solar cell array, that is required to provide the desired electrical output.

To determine the approximate primary parabolic reflector diameter, it is noted that solar insolation, that is the power of the incoming sunlight per unit area, reaching the surface of the earth is approximately 1 kilowatt per square meter (1 kW/m²) or 100 miliwatts per square centimeter (100 mW/cm²). The efficiency of the solar to electrical conversion element is also a primary determining factor in the diameter of the reflector required. In this example, the efficiency is taken from FIG. 6 as will be described. The diameter of the primary parabolic reflector can be calculated from the following relationship:

where:

P is the electrical power output required in kilowatts; I is the approximate value for solar insolation, that is approximately 1 kW/m²; S is the area of the shadow cast by the conversion module;

D is the diameter of the primary parabolic reflector; and E is the conversion efficiency of the conversion module.

In the next step, it will be determined what focal area is required for triple junction solar cells used as a conversion module. The focal area and its radius r can be determined by noting the technical specification for triple junction solar cells. For example, from the manufacturer's data, maximum efficient output can be obtained with an intensity range of 200 to 500 suns and operating the cells with a safety margin at 450 suns would produce an output of approximately 14 W/cm² of area of the solar cell array. Then, to generate an electrical output of 1.36 kilowatts for example, dividing 1,360 watts by 14 W/cm² yields a result of 97 square centimeters. Thus, 97 cells, each having an area of 1 cm² would be required and would take up an area of approximately 97 square centimeters. Because the cells are square and must be fit into a roughly circular area, the overall focal area required for illumination of the cell array will be slightly larger or approximately 100 square centimeters (11.28 cm diameter). This arises from the fact that in practice, geometric incongruities caused by fitting a plurality of square, triple junction cells into an array forming a circular area will require a circle having an area slightly larger than 97 square centimeters.

We have previously observed from FIG. 6 that the typical conversion efficiency of a triple junction solar cell array in the presence of 400 to 500 suns of insolation is slightly above 30%. Moreover, the shadow that the conversion module will cast will be approximately 100 cm². Plugging these values into equation (2), the diameter of the primary parabolic reflector will then be: D=2.4 meters. To determine where to position the focal area for a shallowness ratio, f/D of 0.75, we multiply the f/D ratio of 0.75 times 2.4 meters and find that the focal point is 1.8 meters from the center of the primary reflector along the principle axis. At this location it can be determined that the angle θ in FIG. 7A is 45°. Then, it can be determined from equation 1 that the value x, the distance of the focal area from the focal point, is 5.64 centimeters. Thus, in this design example, a triple junction solar cell in a circular array having an area of 100 square centimeters for use with a primary parabolic reflector having an overall diameter of 2.4 meters is located approximately 5.64 centimeters toward the primary reflector from the focal point. In the alternative embodiment, using a conversion module located at the center of the primary parabolic reflector, this is also the correct position of a secondary parabolic reflector having a diameter of approximately 11.28 centimeters.

Referring now to FIG. 7B, there is illustrated a cross-sectional diagram of a concentrating solar energy receiver 720 according to the present disclosure that is a variation of the embodiment illustrated in FIG. 1A wherein the conversion module to be used employs a solar sensor panel in the location of the far focal area. A primary parabolic reflector is shown at 702 for receiving solar radiation along incident ray 704 which is reflected along the path indicated by 724 through the focal point 706 and further along the dashed lines to a solar sensor panel 710 located at the position of focal area 726 which is also known from the description hereinabove as the far focal area. Coupled with the solar sensor 710 is a thermal cycle engine enclosed within a housing 728. The housing includes extensions 722 which extend beyond the reception surface of the solar sensor 710 and enclose the space between the solar sensor 710 and the plane containing the focal point which is at right angles to the principle axis of the primary reflector 702. The housing extension includes an aperture 706 which is just large enough for the reflected rays from the parabolic reflector 702 to pass through the aperture into the space within the housing in front of the solar sensor 710. It will be observed that the heat energy contained in the radiation that enters the housing area will tend to be contained therein and contribute to the incidence of solar energy into the input heat exchanger of the thermal cycle engine within the housing 728. As was mentioned hereinabove, the thermal cycle engine includes a mechanical coupling from the output of the thermal cycle engine to an electric generator.

Other features may be incorporated in the specific implementation of the concentrating solar energy receiver of the present disclosure. For example, the primary reflector, or some other portion of the structure may include one or more lightning rod or arresting devices to prevent lightning damage to the receiver. The reflectors and the reception surfaces may include a protective coating to retard oxidation or deterioration of the reflective surfaces or solar sensing surfaces. The reflectors may be protected from moisture precipitation, particulates, debris or other contaminants by a covering or from hail and other objects by a screen that may be fixed or movable. Accessory panels or deflectors may be utilized to minimize the disturbance of the receiver components by wind. In other examples, solar energy may be collected in a concentrating solar energy receiver of the present disclosure for application to other uses or conversion to other forms. One advantageous implementation may collect heat energy for heating water or other liquids, gases or plasmas. Heat transferred to such materials may be readily transported to other locations or structures. As solar sensing and energy storage technologies develop, selective portions of the solar radiation spectrum may be collected and converted, processed or stored for a variety of applications. For example, the ultraviolet wavelengths, those wavelengths shorter than 380 nanometers may be received, collected and applied to industrial or scientific processes. Or, variations of the basic principles of the present disclosure may be adapted to reception of solar radiation at locations above the earth's atmosphere where wavelengths above and below the visible spectrum of solar radiation are unaffected by absorption or other attenuation of their intensities.

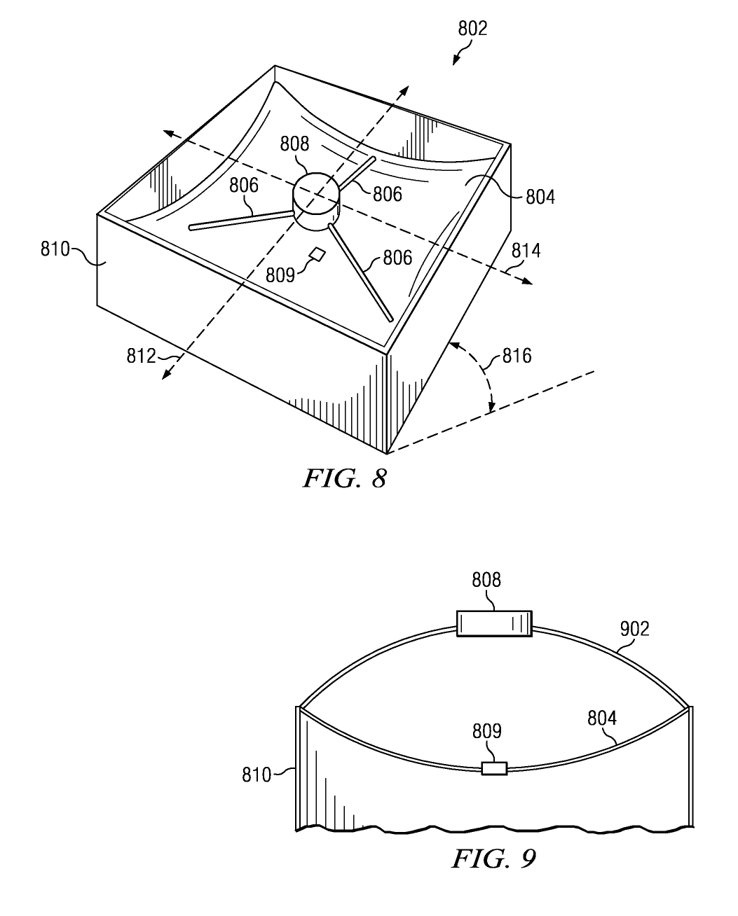

Referring now to FIG. 8, there is illustrated an alternative embodiment of a solar energy receiver comprised of a solar energy receiver pod 802. The solar energy receiver pod 802 consists of the primary reflector 804, as described previously herein with respect to FIG. 1A. Mounted above the primary reflector 804 on three support members 806 is the secondary reflector 808. Of course, other types and numbers of support members may be used. The operation of the primary reflector 804 and the secondary reflector 808 is in the same manner described previously hereinabove. However, the primary reflector 804 rather than being the circular shape described previously with respect to FIG. 1A, is configured in a square configuration with a parabolic surface wherein each side of the primary reflector 804 is of equal size to each of the other sides. This enables the primary reflector 804 to be fitted within a square housing 810 comprising a four-sided square box. The assembled primary reflector 804, secondary reflector 808 within the housing 810 comprises the solar energy receiver pod 802 (the tracking mechanism is not shown for simplicity).

When assembled with other solar energy receiver pods 802, the solar energy receiver pod 802 may move in a number of different directions. The solar energy receiver pod 802 may rotate along a columnar axis 812. Additionally, the pod 802 may be configured to rotate along a row axis 814 perpendicular to the columnar axis 812. Finally, the entire pod 802 may rotate up on its edge along an arc 816. This would provide the ability for the pod 802 to track the sun making the operation of the solar energy receiver pods 802 more effective.

The secondary reflector 808 focuses the received solar energy on the solar sensor and conversion device 809. While the solar energy receiver pod 802 of FIG. 8 illustrates that the secondary reflector 808 is supported above the primary reflector 804 using a series of support members 806, in an alternative embodiment, as illustrated in FIG. 9, the secondary reflector 808 may be suspended above the primary reflector 804 within a transparent covering 902. In this embodiment, a transparent covering 902 encloses the pod assembly 802 and extends to each edge of the housing 810 in order to protect the primary reflector 804 from debris and external environmental conditions. Since the transparent covering 902 covers the entire opening of the housing 810, the secondary reflector 808 may be integrated within the transparent covering 902 such that when the transparent covering 902 is in position, the secondary reflector 808 is suspended in the appropriate position above the primary reflector 804. This eliminates the need for the supporting members 806. The transparent covering 902 comprises a glass or highly transparent material. The glass or transparent material may be coated with a material that allows a range of light spectrum to pass through while the glass or transparent material serves to protect the solar sensor and conversion module 809 and surface of the primary reflector 804 from dust or other interfering contamination. Such spectrum filtering may be accomplished by coating the transparent material or glass with an optical filter material such as that described hereinabove.

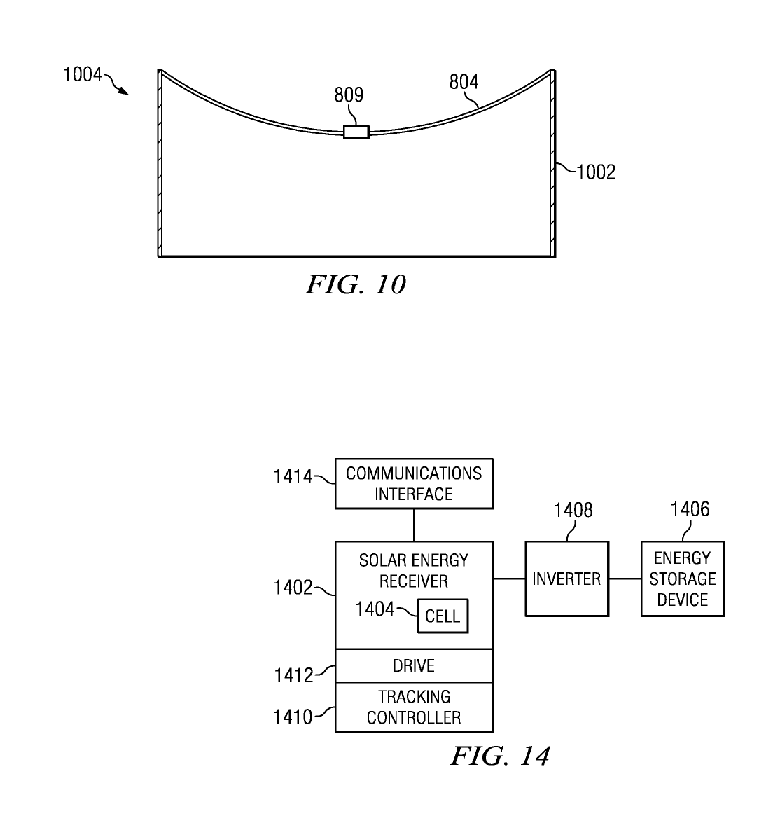

Referring now to FIG. 10, there is illustrated an integrated primary reflector 804 and heat sink 1002. As discussed previously, a heat sink 1002 may be included with the primary reflector 804 to remove heat generated by the solar radiation that is being collected by the solar energy receiver. Rather than utilizing a separate heat sink that is connected to the primary reflector 804 via some type of thermally conductive adhesive, the primary reflector 804 as well as the heat sink portion 1002 may be configured in a single assembly 1004. The assembly 1004 may be made of a single block of metal or other material which may be extruded. One portion of the assembly 184 is reamed or formed to create the parabolic dish that forms the primary reflector 804 on one side that is polished to create a highly reflective surface or is coated with a highly reflective film that reflects a certain spectrum of light while being transparent to other energy spectrum. This allows pass through light to be absorbed by the primary reflector 804 and dissipated in the surrounding air and to any thermally conductive device that may be attached to the primary reflector 804 such as the heat sink 1002. The heat sink 1002 conveys heat away from the conversion device 809 to limit damages to the device. This combined assembly 1004 would then be placed within the housing 810 as described previously.

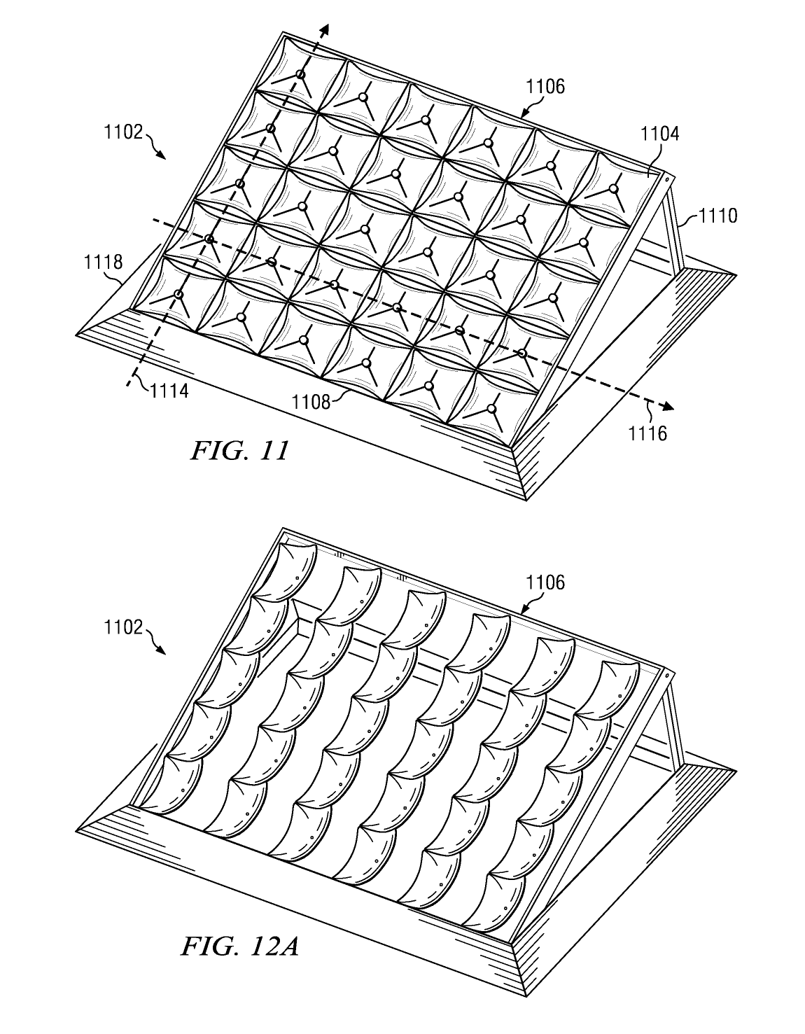

Referring now to FIG. 11, there is more fully illustrated a solar receiver module 1102. The solar receiver module 1102 comprises a 5×6 array of solar energy receiver pods 1104 without an individual tracking mechanism. Each of the solar energy receiver pods 1104 are configured the same as the receiver pods described previously herein with respect to FIGS. 8-10. The solar energy receiver pods 1104 are arrayed together such that the entire pod array assembly 1106 may be raised and lowered along an edge 1108 using an elevating mechanism 1110. While FIG. 11 illustrates that the elevating mechanism 1110 comprises a mechanical arm for raising and lowering the array assembly 1106 along its bottom edge 1108, it should be realized that other types of mechanisms that are hydraulic, electric, mechanical, etc., may be used for raising and lowering the array assembly 1106 along its bottom edge 1108 or any other edge. Additionally, it should be appreciated that while a 5×6 array of solar receiver pods 1104 is illustrated with respect to FIG. 11, arrays of any size and/or configuration may be utilized according to aspects of the present invention.

As described previously with respect to FIG. 8, each of the solar energy receiver pods 1104 in addition to being raised and lowered via the elevating mechanism 1110 may also rotate about its columnar axis of rotation 1114 and additionally may be rotated along its row axis of rotation 1116. In each case, the solar receiver pods 1104 in a particular column are each chained together such that each pod 1104 within the column will rotate the same amount about the columnar axis of rotation 1114. Similarly, each of the solar energy receiver pods 1104 are chained together within a separate row such that they may rotate the same amount about the row axis 1116. While the present description describes that each of the pods are chained with other pods in the same row and column, in alternative configurations, the solar receiver pods 1104 may be configured such that they are only chained with other pods in the same column or alternatively only with pods only in the same row. In yet another embodiment, each of the solar energy receiver pods 1104 may be configured such that each pod is individually controlled rather being controlled within similar pods in the same row or column in a staggered placement whereby an adjacent pod on a higher row is not shadowed from the sun by the adjacent pod below it.

The module assembly 1102 may be lowered via the elevating mechanism 1110 down into a protective enclosure 1118. The protective enclosure 1118 in the illustration of FIG. 11 includes slanted or aerodynamically shaped sides. Each of the four sides of the protected enclosure 1118 defines within the center a space into which the module assembly 1106 may be lowered. When lowered into the protective enclosure 1118, the module assembly 1106 will lie below the top edge of the protective enclosure 1118. The slanted or aerodynamically shaped sides of the protective enclosure 1118 provide for aerodynamic airflow over and around the protective enclosure 118 while protecting the module assembly 1106 lying down therein when the pods are retracted/lowered into the enclosure. The individual pods 1104 may be locked down to prevent dislodgment under heavy wind conditions. In additional configurations, the aerodynamic shape of the sides of the protective enclosures 1118 may be configured in such a manner such that a slight vacuum is created within the area above the protective enclosure and above the surface of the pod assembly 1106. In this case, dust, dirt or other particulate matter that would lie on the surface of the individual pods 1104 of the pod assembly 1106 would be pulled off of the solar energy receiver pods 1104 by the slight vacuum as wind passes over the protective enclosure 1118. Other aerodynamic shapes are possible that enable the generation of wind eddy currents that causes changes in the flow of the wind or channels the wind such as to function as a cooling medium or to provide for secondary energy conversion such as from mechanical energy to electrical energy.

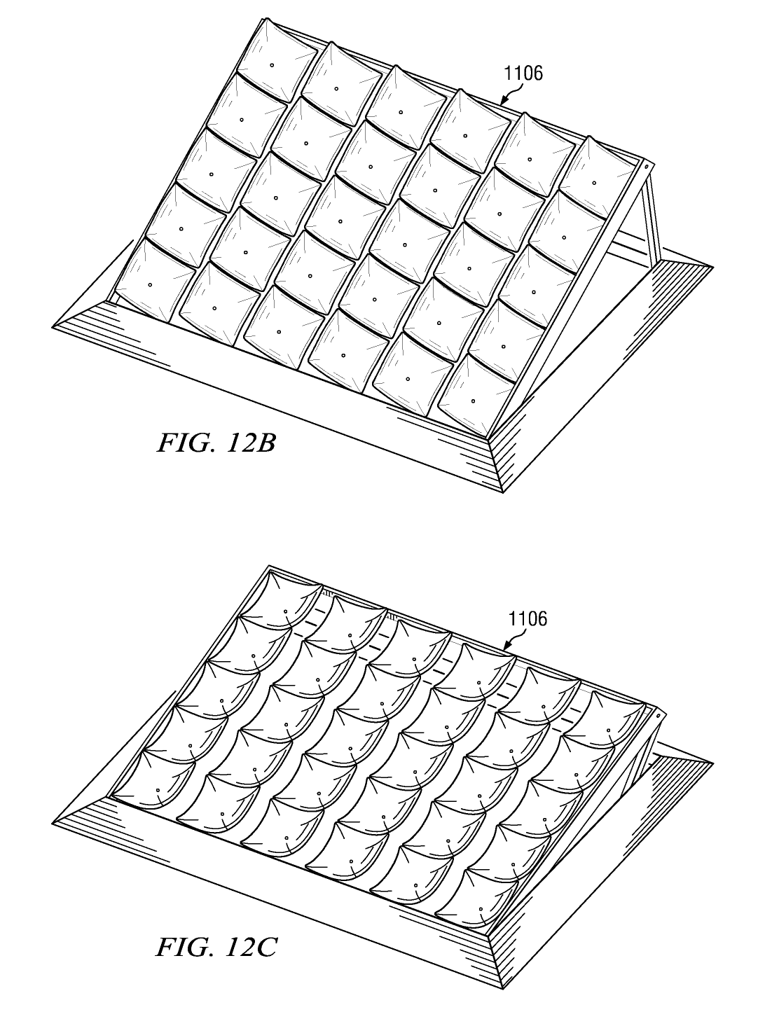

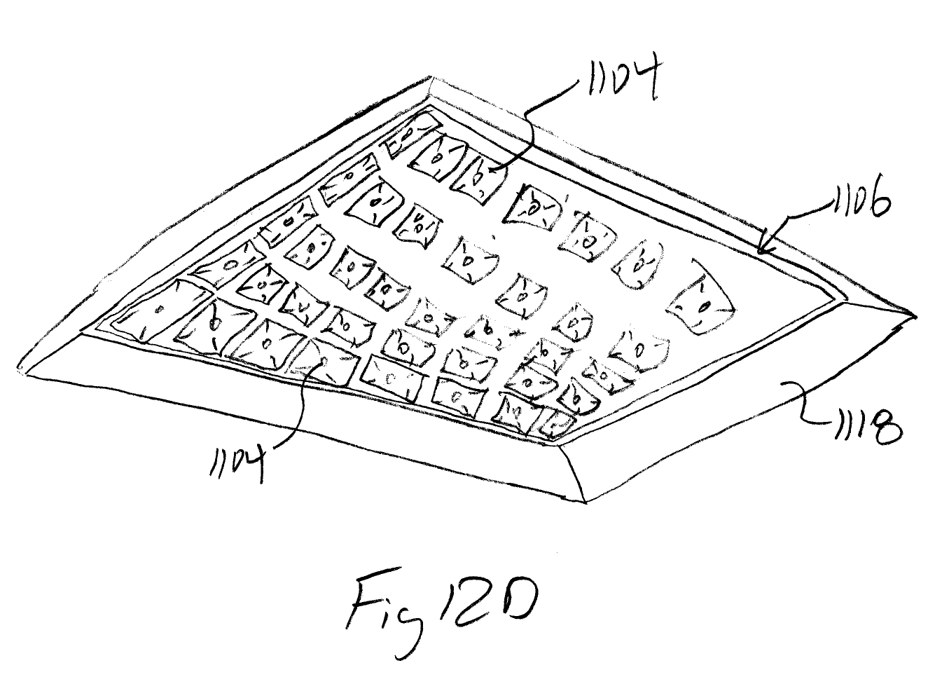

Referring now to FIGS. 12A-12D, there are illustrated the pod assembly 1106 in various positions and configurations within the module assembly 1102. In the case of FIG. 12A, the pod assembly 1106 is in a raised position and each of the individual pods 1104 are rotated about their columnar axis 1114 such that the primary reflectors are focused in a direction generally to the left of the figure. In this case, there is no change of the orientation with respect to the rows and each of the solar receiver pods 1104 are chained with other solar receiver pods 1104 in its same column. Each pod is enclosed by a protective cover.

Referring now to FIG. 12B, the pod assembly 1106 is still in the same raised position as described with respect to FIG. 12A; however, each of the individual pods 1104 are rotated about its columnar axis 1114 such that the focus of each of the primary reflectors is in a direction generally to the right of the figure. With respect to FIG. 12C, the pod assembly 1106 is now in a lower position between a maximum extended position and a fully lowered position. Additionally, each of the individual solar receiver pods 1104 are configured in a direction such that they rotate about the columnar axis 1112 to point the focus of the primary reflector generally perpendicularly to the plane of the pod assembly 1106. Finally, in FIG. 12D, the pod assembly 1106 has been completely lowered within the protective enclosure 118. When lowered within the protective enclosure 1118, each of the individual pods 1104 are protected by each side of the protective enclosure 1118 as described previously.

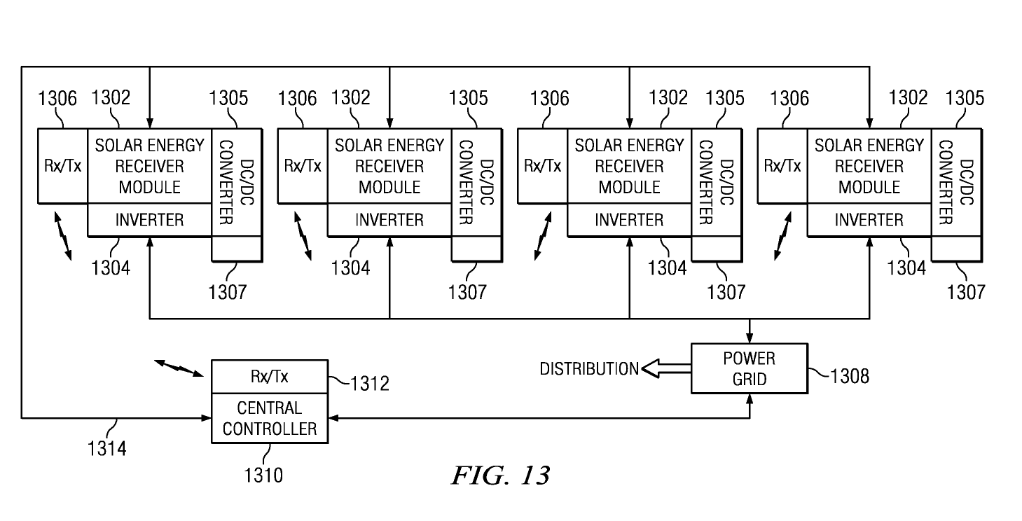

Referring now to FIG. 13, there is illustrated the manner in which the solar energy receiver module 1302 may be interconnected with other modules and controlled. Each solar energy receiver module 1302 includes an inverter 1304 and transceiver circuitry 1306. The solar energy receiver module 1302 comprises the structure described previously with respect to FIGS. 11 and 12. The inverter 1304 turns the DC energy generated by the solar energy receiver module 1302 into AC electrical energy that may be utilized within an associated power grid 1308. Each of the inverters 1304 associated with a solar energy receiver module 1302 connects with the power grid 1308 such that all power may be distributed to needed areas. The solar energy receiver module additionally includes a DC/DC converter 1305 for turning the DC energy generated by the solar energy receiver module 1302 into a regulated DC voltage. By incorporating individual inverters and converters with each solar energy receiver module 1305 such modules can be made to be portable as standalone units for personal use thereby providing portable AC and/or DC power to power personal electronic devices such as personal computers, personal data appliances (“PDA”) and other popular personal consumer electronic products. Each unit can be equipped with appropriate universal power receptacles such as for a standard 3-pronged connector for AC or a USB outlet for 5V DC devices. In addition the components that make up such a portable unit can be made to be collapsible such as to occupy less space for travel or shipment and be reassembled when it is to be used.

The regulated DC voltage can be used locally for storage in a battery 1307 or powering devices or act as a power smoother and off hours power supply for the solar energy receiver module 1302. The DC/DC converter 1305 also enables the solar energy receiver module 1302 to operate in a standalone mode where the module is powered by the converter 1305 or the battery 1307. Additionally, the transceiver circuitry 1306 enables each of the solar energy receiver modules 1302 to be in wireless communication with a central controller 1310 that also includes transceiver circuitry 1312. Through the wireless connection via the transceiver circuitry 1312, the central controller 1310 may control the operation of the solar energy receiver modules 1302 and control the configuration of individual pods within the solar energy receiver module and control the manner in which the power grid 1308 is distributing power to buildings or areas associated with particular solar energy receiver modules. Additionally, the central controller 1310 can communicate with a solar energy receiver module 1302 via a wireline connection 1314 rather than the wireless connection via the transceiver circuitry 1312.

The number of pods that are ganged together within a particular solar energy receiver module 1302 may be electrically configured or connected in numerous configurations to yield the desired power, voltage and current outputs. The ganged arrays may also be electrically connected and integrated with other physically separated ganged arrays or individual pods such as to generate a network or grid of solar generated electricity whereby the components of the electrical network (the pods and modules) are individually controlled and/or synchronized wirelessly for physical orientation and electricity generation and connectivity to the power grid 1308 via the central controller 1310.

In one example, several solar energy receiver modules 1302 may be mounted upon the roofs of a number of different housing units. The individual solar energy receiver modules 1302 would be electrically connected to the power grid 1308 to supply electricity to the housing community in which the personal housing units associated with each of the solar energy receiver modules 1302 were associated. The configuration of FIG. 13 would enable the automatic switching of electricity flow from the solar energy receiver modules 1302 to the power grid 1308 whereby the modules 1302 generating electricity can be made available to other devices connected to the grid and alternatively the grid can provide electricity to the housing units when the solar energy receiver modules 1302 are not generating enough electricity.

The housing units associated with each of the solar energy receiver modules 1302 can be electrically grouped so that the electricity produced and/or consumed by the group can be isolated or connected to the power grid 1308 as a group as each module 1302 is wirelessly controlled from the central controller 1310 and thus each group of housing units may be ganged or integrated electrically to the power grid 1308. Groups of housing units can also be electrically ganged as a higher aggregation of electricity generators or consumers with no foreseeable limits to the number of levels of aggregation. Thus, an entire community of hundred, thousand and more housing units may be controlled as to access to and from the grid 1308.

By incorporating individual inverters and converters with each solar energy receiver module 1305 such modules can be made to be portable as standalone units for personal use thereby providing portable AC and/or DC power to power personal electronic devices such as personal computers, personal data appliances (“PDA”) and other popular personal consumer electronic products. Each unit can be equipped with appropriate universal power receptacles such as for a standard 3-pronged connector for AC or a USB outlet for 5V DC devices. In addition the components that make up such a portable unit can be made to be collapsible such as to occupy less space for travel or shipment and be reassembled when it is to be used.

Referring now to FIG. 14, there is illustrated a further embodiment of a solar energy receiver pod as depicted in FIGS. 8 to 10. The solar energy receiver pod utilizes a solar energy receiver 1402 that utilizes a mechanism for magnifying the solar energy that is directed toward an associated CPV cell or cells. The mechanism may, in one example, comprise that disclosed in U.S. Pat. No. 6,818,818, which is incorporated herein by reference, or a retinal lens or other means of magnification for more specifically focusing solar energy on the photovoltaic cell such as the use of a Fresnel lens. The solar energy receiver 1402 is connected to an energy storage device 1406 through an inverter and/or battery charge controller 1408. The energy created within the solar energy receiver 1402 is provided to the inverter 1408, which converts the energy to a form able to be stored within the energy storage device 1406. In one example, the energy storage device 1406 may comprise a rechargeable battery. The energy storage device 1406 may be used to provide energy to a tracking controller 1410 and drive mechanism 1412. The tracking controller 1410 and driver mechanism 1412 enable the solar energy receiver 1402 to track the sun on one or more axis in order to position the CPV cells to face the sun and enable the generation of electricity and/or heat energy, which may be then provided to externally connected devices. The energy storage device 1406 may be enclosed together with the CPV receiver 1402 within a single enclosure or situated outside of the enclosure connected to externally connected devices.

The inverter 1408 or battery charge controller or other similar type of energy control device, may also be included within the enclosure with the receiver 1402 or connected outside of the enclosure by means of connecting cables or a heat exchanger in the case of heat storage. Thus, a single solar energy receiver 1402 may contain the full complement of devices necessary to track the sun in order to optimize the reception and magnification of the sun's energy onto the CPV cell 1404 to enable conversion of the sun's energy into electricity and other derivative energy for the powering of devices external to the solar energy receiver 1402. The means of connecting these external devices may also be provided for or incorporated into the assembly housing the solar energy receiver such as via an electrical receptacle. Each receiver 1402 may also be equipped with a two-way communications interface 1414 in order for the receiver 1402 to be controlled remotely and/or communicate with external devices through the communications interface 1414.

The assembly of FIG. 14 may be implemented in a stand-alone configuration and may comprise a “plug and play” configuration, wherein all of the necessary components to enable the receiver assembly to generate electricity or other forms of energy such as heat may be included within a single assembly. Such a solar energy receiver 1402 could also be fashioned as part of an overall grid, wherein the necessary electrical connections and mechanical receptacles are separately provided for the ready mating of the receptacle with the receiver assemblies. The receiver 1402 will be enclosed within a hermetically sealed container with all of the necessary connecting cables either embedded or protruding out of the receiver 1402 for connection to external devices. If a glass material or other light transparent material is used, the material itself would act as a mechanical support or holder for such components as a secondary lens as described herein.

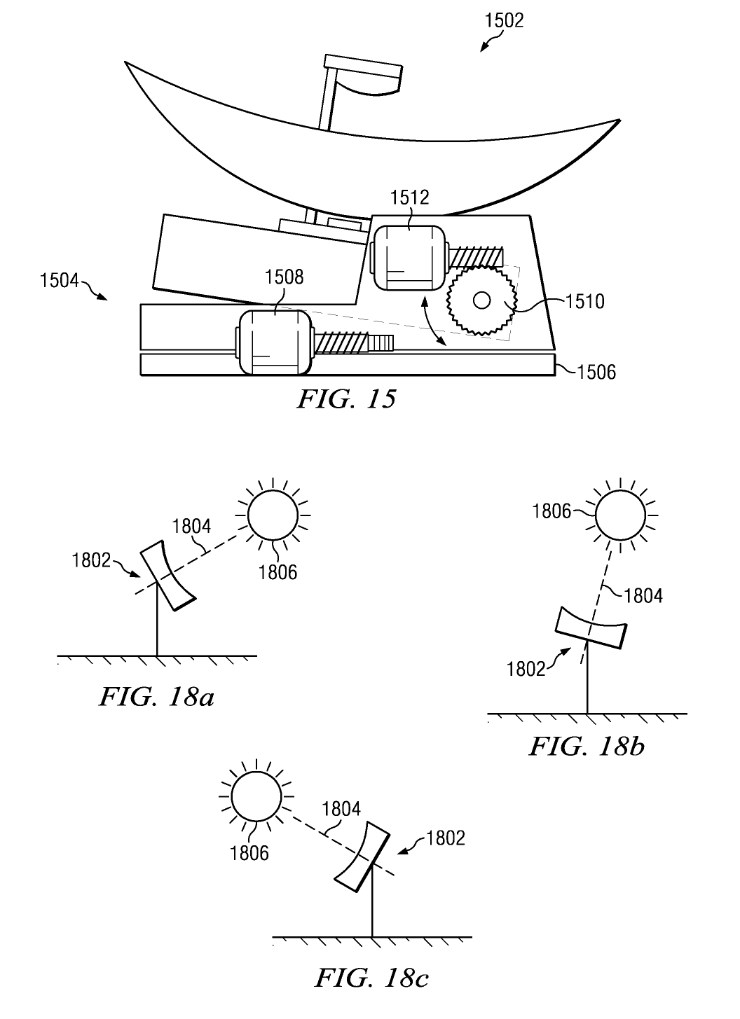

The solar energy receiver 1402, as mentioned hereinabove, may be configured to operate upon one or more axis in order to position the CPV cell 1404 with respect to the sun. Referring now to FIG. 15, there is illustrated a side view of a solar energy receiver 1402 that may be rotated about three different axis, namely the X, Y and Z axis. The receiver structure 1402 is connected to a drive mechanism 1504 that contains a number of different parts providing movement of the solar energy receiver 1402 about the X, Y and Z axis. A base structure 1506 includes a drive gear 1508 that enables the entire solar energy receiver 1402 to be rotated about the Z axis. Gear 1510 enables the solar energy receiver 1402 to be rotated about the Y axis. Finally, a driver and worm gear 1512 enables the solar energy receiver 1402 to be rotated about the X axis. Thus, using the various drive and gear assemblies, the solar energy receiver 1402 can be rotated about three different sets of axes. This degree of movement would allow the receiver 1402 to track the movement of the sun.

Referring now also to FIG. 16, there is illustrated a two axis implementation of a solar energy receiver 1402 using a parabolic dish 1602 for solar energy magnification. A drive mechanism 1604 orients the parabolic solar receiver which may be comprised of varying shapes and curvatures as described in U.S. Pat. No. 6,818, 818. The drive mechanism 1604 enables the solar energy receiver 1402 to face the sun to optimize and magnify the reception of solar energy by the CPV cell 1606. The drive mechanism 1604 comprises any number of mechanical devices for rotating the parabolic dish 1602 illustrated in FIG. 16. In one embodiment, the mechanism encompasses rollers for applying a frictional force to the convex surface (i.e., the backside) of the parabolic dish to move the parabolic dish into a position to receive solar energy. Additionally, a rail mechanism could be incorporated onto the convex side of the parabolic dish 1602 providing a guiding and traversing track that is coupled with some type of drive motor. A further implementation includes a pivot point of the dish enabling tilting of the dish 1602 to face one direction and additional pivot points may be used to tilt the dish 1602 in other directions.

Referring now also to FIG. 17, alternative forms of solar energy magnification may be utilized rather than the parabolic dish illustrated in FIG. 16. A Fresnel lens 1702 can be mounted within a housing 1704. The housing 1704 is pivoted and/or rotated via associated drive gears and rollers that are interfaced with the housing 1704. Driving of a Fresnel lens housing 1704 utilizes one or more of the components described hereinabove with respect to the manner for driving either of the implementations illustrated in FIGS. 15 and 16. Additionally, the Fresnel lens 1702 could be included with the various other receiver components such as the inverter/controller and two way communications capability in order to optimize the magnification and reception of solar energy upon associated CPV cells and convert the sun's energy to electricity or derivative energy forms utilized to power or heat an external device.

A major challenge in the implementation of a self-tracking solar energy receiver is the process adopted for tracking and maintaining the accuracy of the tracking process with respect to the sun. The tracking of the sun's position may be achieved in a number of different ways. These include using a fixed algorithm that depends upon a known position of the sun during the course of a calendar year and varies based upon the natural rotation of the earth with respect to the sun or by measuring the relative strength of the sun incident upon a particular receiver using two or more light sensors.

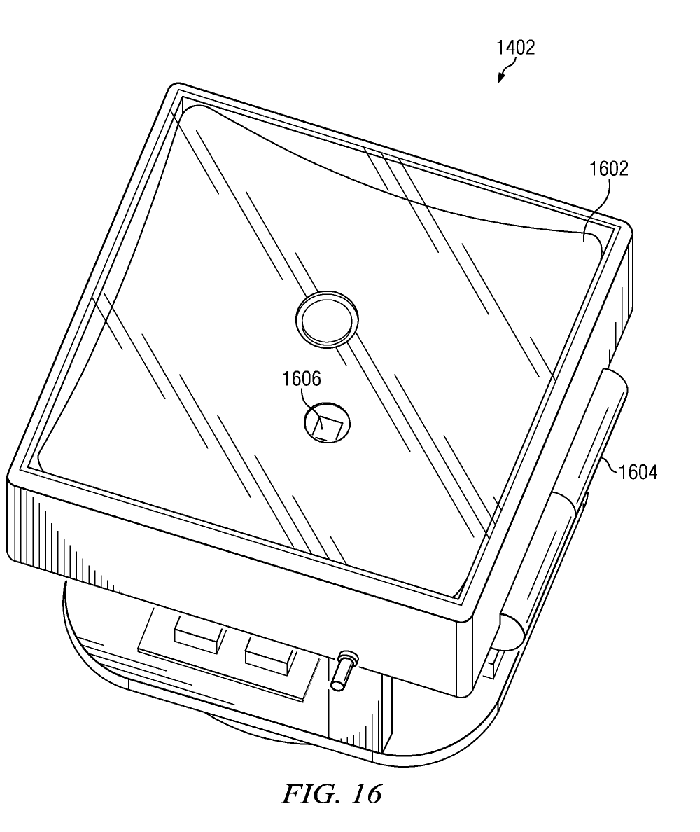

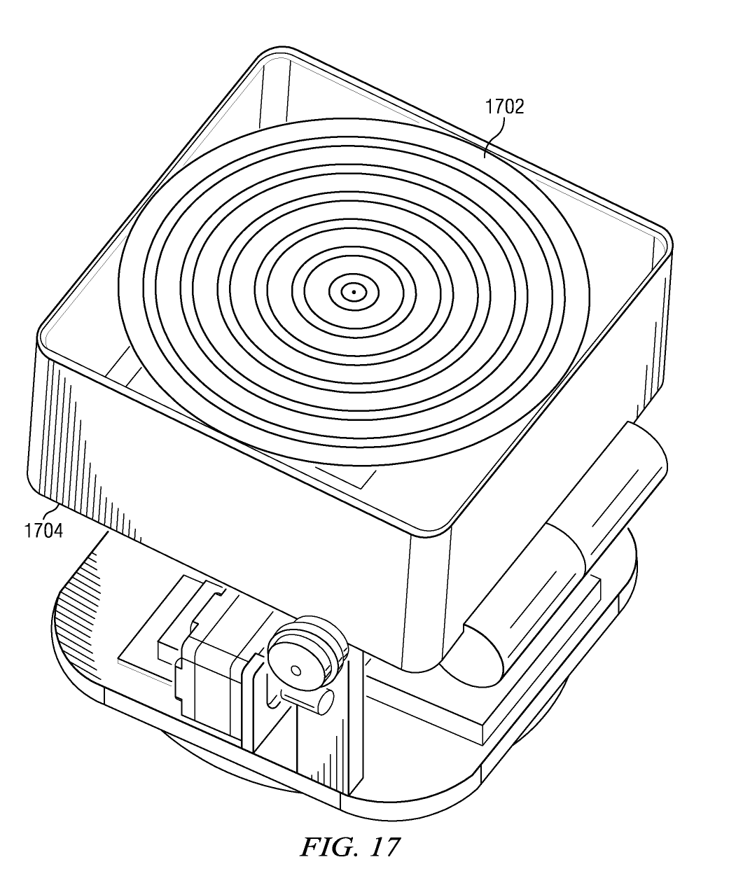

Referring now to FIGS. 18A-C, there is illustrated the use of a fixed algorithm implementation in a solar energy receiver. In a fixed algorithm implementation, the solar energy receiver 1802 may have its position manually set in relation to a known position of the rising sun such as that illustrated in FIG. 18A, and the orientation of the solar energy receiver 1802 is adjusted automatically by the way of associated motors that rotate the receiver 1802 along one or more axis to correspond to the known path of the sun 1806 during the course of the day. Each morning, the receiver 1802 returns to a fixed initial orientation to begin its tracking cycle again. This initial position would of course change based upon the time of year.

In FIG. 18A, the solar energy receiver 1802 is shown with its axis 1804 placed in a position to enable it to track the sun 1806 in the early morning shortly after sunrise. In this case, the axis 1804 is pointing low toward the eastern horizon responsive to the sun 1806 rising. The controlling algorithm would incorporate a known position on the horizon at which the sun would be rising based upon historical data stored within a memory of the solar energy receiver 1802. As the day progresses, as illustrated in FIG. 18B, the solar energy receiver 1802 is in a more upright position with the axis 1804 directed almost perpendicular to the ground. This is due to the fact that the sun 1806 has risen to almost a high noon position as the time of day has passed. Finally, as illustrated in FIG. 18C, the solar energy receiver 1802 directs its axis 1804 low on the western horizon to track the sun 1806 as it begins to descend below the horizon in the west.

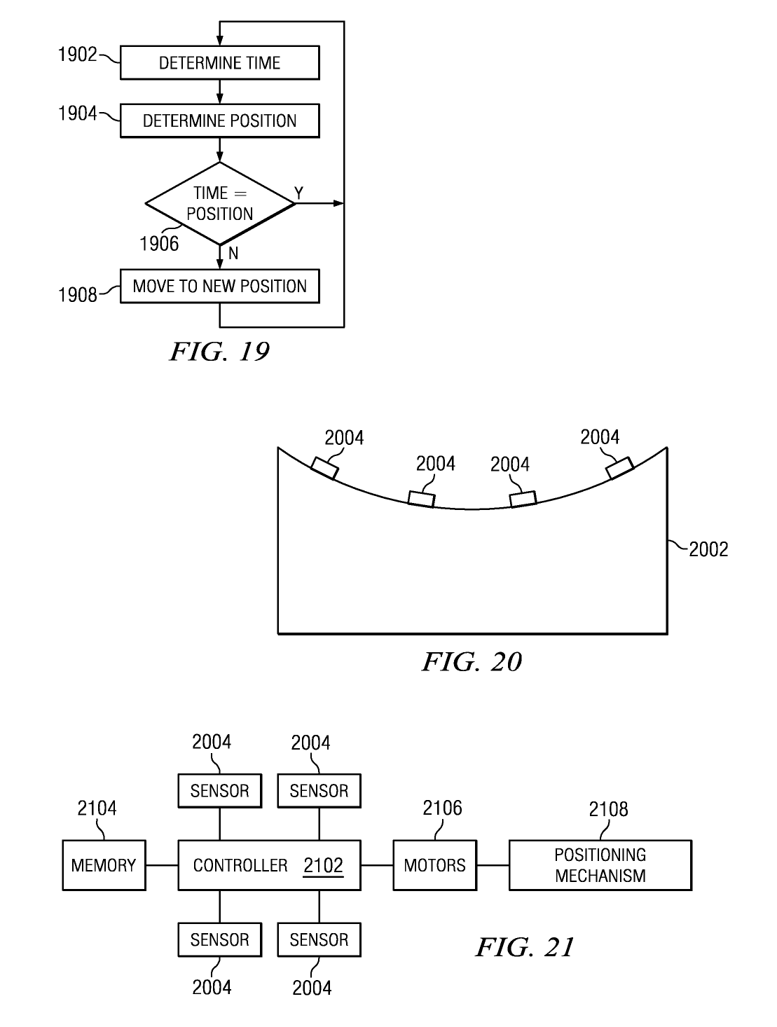

Referring now to FIG. 19, there is illustrated a flow diagram describing the process by which the control algorithm controls the operation of the receiver 1802 during the course of a day. Initially, the time of day is determined at step 1902. Next, the position of the solar energy receiver is determined at step 1904. Inquiry step 1906 determines whether the present time and position of the solar energy receiver 1802 are correct with respect to each other. This could be achieved using a table that indexes the time of day to a particular directionality of the central axis 1804 of the solar energy receiver 1802. If the time of day and position of the receiver correspond as they should, control passes back to step 1902 to continue to monitor the time of day and position of the receiver. If inquiry step 1906 determines that the time of day and position of the receiver are not properly indexed with each other, the drive assembly of the solar energy receiver 1802 is used to move at step 1908 the receiver to the new position as indicated by the positioning data stored in association with the algorithm. Control will then pass on to step 1902 to continue the position and time monitoring process.

Referring now to FIG. 20, there is illustrated an alternative methodology for implementing a self-tracking solar energy receiver wherein the solar energy receiver 2002 includes a plurality of light sensors 2004 affixed to the surface thereof to enable the solar energy receiver 2002 to align the receiver with the sun. A typical methodology utilizes more than one sensor 2004 and provides a control mechanism wherein the sensor 2004 which detects a stronger light energy is determined to be the sensor that is pointed more directly toward the sun. A sensor 2004 experiencing less sunlight means that the sensor 2004 is not directly pointed at the sun. A control process orients the receiver 2002 by relative detection of the sunlight by the different sensors 2004. Control motors are actuated to cause the receiver 2002 to rotate to a position to orient the receiver 2002 toward the detected sunlight.

Referring now to FIG. 21, there is illustrated an implementation of one such control mechanism associated with the solar energy receiver 2002. Each of the sensors 2004 provides sensor information to a central controller 2102. In one embodiment, the sensors 2004 are equally spaced from each other but other configurations are also applicable. While the present description discloses the use of four sensors 2004 with respect to the solar energy receiver 2002, any number of sensors or sensor arrays may be utilized in order to optimize the positioning capabilities of the solar energy receiver 2002. The central controller 2102 utilizing the received sensor information and control information provided from a local memory 2104 determines a present position of the solar energy receiver 2002 with respect to the sun. Once a determination of the position of the solar energy receiver 2002 has been made by the controller 2102, a new position to better orient the central axis of the solar energy receiver 2002 toward the sun is made by the controller 2102. The controller 2102 sends actuation signals to various drive motors 2106 that are used to drive a positioning mechanism 2108 to orient the solar energy receiver 2002 into the new position as determined by the controller 2102. The controller 2102 reacts to the information provided from the light sensors 2004 in a manner to reduce the rotational travel of the solar energy receiver 2002 such that only incremental positional changes are provided to the drive motors 2106 and positioning mechanism 2108 thus resulting in more accurate positioning of the receiver 2002.

Often, there will be mismatches between the information provided from the various light sensors 2004 such that the light sensors provide different light strength information even when they are receiving the same amount of incident light. This will of course affect the tracking mechanism's accuracy. In order to improve tracking accuracy, an algorithm can be used within the controller 2102, which detects changes of relative light intensity of different light sensors 2004 when the drive motors 2106 and positioning mechanism 2108 move the solar energy receiver 2002. The controller 2102 determines accurate positioning with respect to the sun by monitoring the output of the light sensors and determining when a maximum light detection position is detected for each of the sensors. Comparisons of the output of the light sensors will be made to compensate for the light intensity changes of the sun during motor movement. Thus, the maximum light intensity reading for each of the sensors 2004 is used in determining a most likely direction of the sun rather than the absolute value detected by the sensors 2004. By such an implementation of multiple sensor arbitration, the controller 2102 can be self-initiating in its initial positional orientation toward the sun, which is of great utility for an array consisting of more than one self-tracking solar energy receiver 2002. This would remove the requirement for the solar energy receivers 2002 to be physically linked even if the solar energy pods in the array are physically linked through an inflexible frame. The solar energy receivers 2002 would not need to be preset on the frame, nor would they need to be aligned prior to shipment and installation, thus reducing the time and effort required in installation in the field. Thus, the self-tracking ability enables an array of solar energy receivers 2002 to be self-aligning.

However, self-alignment requires that the tracking sensors operate accurately, which may not be the case when one sensor loses sensitivity for one reason or another, such as becoming dirty or degrading in its operational capabilities. In order to avoid a creeping misalignment when the solar energy receiver initializes to face the sun, the initial daily starting position may be compared by the controller 2102 to a known reference coordinate such as the historical initial positioning of the solar energy receiver 2002 during the course of the calendar year. This type of information is stored within the memory 2104. Alternatively, and/or simultaneously, the relative intensity of light sensed by a sensor 2004 with respect to another sensor may be compared to the historical relative strength of the subject sensors with this data also being stored within the memory 2104. Such relative strength information is measured against more than one reference sensor thereby providing a means of arbitrating the true position of the malfunctioning sensor and generating correctional information responsive thereto.

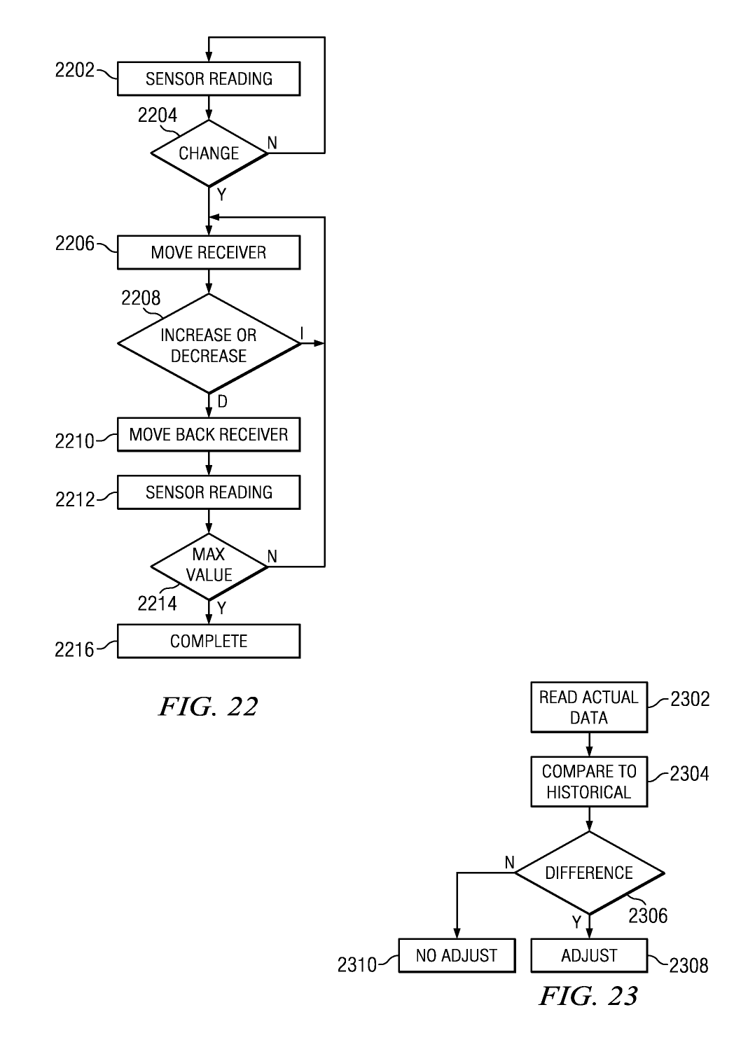

Referring now to FIG. 22, there is illustrated a flow diagram illustrating one manner in which the controller 2102 controls the operations of the solar energy receiver 2002. Sensor readings are taken from the sensors 2004 at step 2202. A determination is made by the controller 2102 as to whether there has been a change in the sensor readings since the last time the readings were taken. If not, the sensors are continuously monitored at steps 2202 and 2204. If inquiry step 2204 determines a change in the sensor readings, the receiver 2002 is moved in a first direction at step 2206. After the receiver 2002 is moved, inquiry step 2208 determines whether the light sensor readings have increased or decreased. If the light sensor values have increased, control passes back to step 2206 and the receiver 2002 is again moved in the first direction. If inquiry step 2208 determines that there has been a decrease in the detected light intensity, the receiver 2002 is moved in the reverse direction at step 2210. New sensor readings are taken at step 2212 and inquiry step 2214 determines whether a maximum light intensity value has been detected. If so, the process is completed at step 2216. If inquiry step 2214 determines that a maximum sensor value is not detected, the receiver 2002 is again moved in the second direction at step 2206. The process continues until the maximum light intensity sensor value is detected and the process is completed at step 2216.

Referring now to FIG. 23, there is illustrated a flow diagram describing the manner in which the misalignment caused by loss of sensor sensitivity or other types of environmental conditions may be accounted for within the control system of the present disclosure. Initially, at step 2302, the actual sensor data is read from the sensors 2004. This sensor data is compared at step 2304 with the historical data that has been previously monitored from the sensor and stored within an associated memory 2104. Inquiry step 2306 determines if there are drastic differences between the actually monitored data and the historical data. If changes are present, the position or calibration of the sensors is adjusted at step 2308 to correct for any drastic differences. If inquiry step 2306 detects no significant differences between the actual data and the historical data, no adjustments are necessary at step 2310.

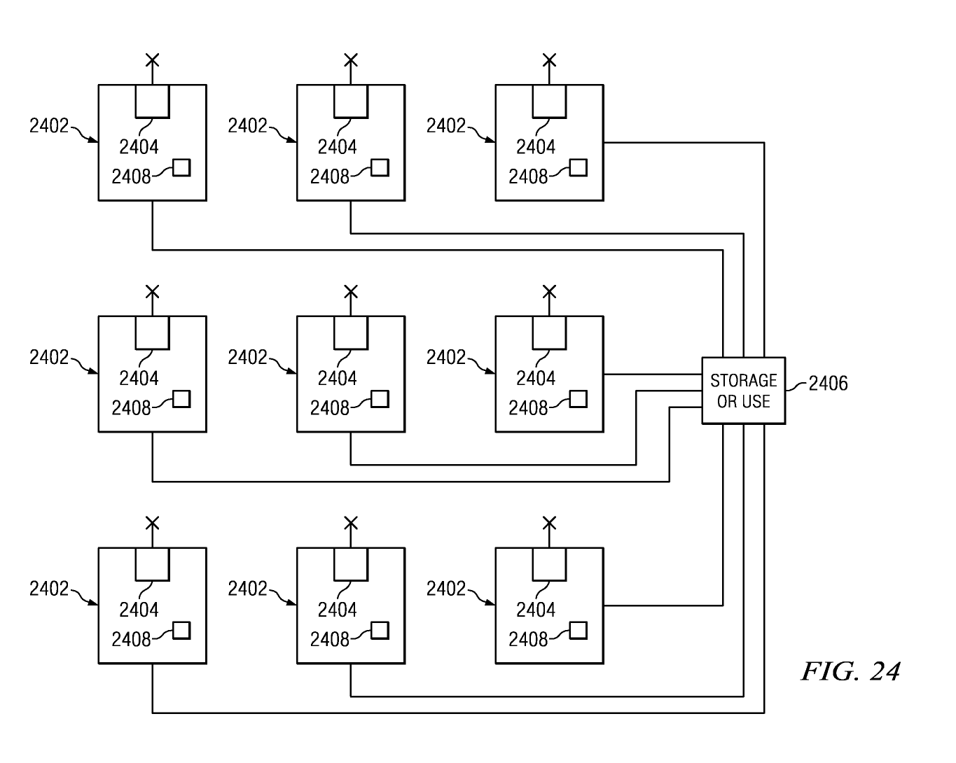

Referring now to FIG. 24, there is illustrated an array of solar energy receivers 2402 that are able to communicate with each other via wireless communications connections 2404. This allows each of the solar energy receivers 2402 to receive information concerning the location of the sun, control its tracking accordingly and aggregately provide information to a battery storage or use location 2406. In the case of an array of solar energy receivers 2402, by equipping each receiver 2402 with a communications interface 2404 which may be a wireless means as illustrated in FIG. 24, or alternatively, could include other wireline communications capabilities, each receiver 2402 may communicate with other receivers within the arrays as well as with receivers in other arrays or with other arrays in the aggregate to receive and provide information regarding the position of the receiver 2402 with respect to the sun. By sharing this type of information in the aggregate, positional accuracy with respect to the sun may be increased by enabling each solar energy receiver 2402 to correct its position in the event of a malfunctioning sensor or otherwise based upon information from other sensors. Thus, if the sensors on any particular receiver 2402 were to fail, the solar energy receiver 2402 utilizes information received from adjacent or adjoining receivers 2402 in order to track the position of the sun. Each solar energy receiver 2402 could additionally include a reference positional device such as a GPS receiver 2408. The GPS receiver 2408 is used for aligning the solar energy receiver 2402 with respect to the sun. A further benefit of the inter-receiver communications capability is the synchronization of orientation of the arrays within a field of arrays to maximize the positional reception of the sun's energy as receivers that are further away from the rising sun may not be able to detect the sun until it reaches a sufficient height in the sky. Such early detection of the sun by the solar energy receivers 2402 that are physically distant from the sun would increase the duty cycle of energy generation by each receiver or group of receivers and arrays if they would be focused on the sun at some point prior to the sun becoming visible over the horizon or terrain.

The communications interface 2404 additionally enables the receivers 2402 to be placed remotely from each other and still remain electronically connected to enable the aggregation of energy produced individually by the receivers 2402 at a central power storage/use location 2406. The ability to self-track the sun would enable the solar energy receiver 2402 to be utilized in a stand-alone configuration to provide energy to one more devices such as in providing DC power to DC operating devices, wherein the DC-to-DC converter may be incorporated directly into the receiver or provided as a separately connected device. The same procedure would apply to a power inverter that would be used to convert DC power to AC power. An additional utility for a self standing solar energy receiver 2402 is the independent powering of electric vehicles such as an electric bicycle (e-bike), which may require several receivers to be electrically ganged together to provide the necessary voltage and current required.

Using the above-described solar energy receiver module, an array of solar energy receivers may be ganged together to produce electrical energy for use by the power grid. The ganged structure may allow the solar energy receivers to follow the sun at an optimal receiving angle and still place the individual receivers within a protective enclosure should environmental wind or other conditions potentially provide damaging operating conditions to the solar energy receivers.

It will be appreciated by those skilled in the art having the benefit of this disclosure that this array module of parabolic solar energy receivers provides an efficient manner of generating electricity while protecting the array from environmental conditions. It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

What is claimed is:

1. A solar energy receiver array, comprising:
a plurality of solar energy receivers arranged in an X by Y array;
a protective housing including a plurality of sides defining an opening therein; and
wherein the plurality of solar energy receivers arranged in the X by Y array may lowered into the opening within the protective housing to protect the plurality of solar energy receivers arranged in the X by Y from external winds.

2. The solar energy receiver array of claim 1, wherein a first edge of the X by Y array may be raised from a first position within the protective housing to a second position outside of the protective housing and further wherein the X by Y array pivots on a second edge of the X by Y array as the first edge of the X by Y array moves from the first position to the second position.

3. The solar energy receiver array of claim 1, wherein each of the plurality of solar energy receivers of the X by Y array rotate about a first columnar axis.

4. The solar energy receiver array of claim 3, wherein each of the plurality of solar energy receivers of the X by Y array rotate about a second axis perpendicular to the first columnar axis.

5. The solar energy receiver array of claim 1, wherein each of the plurality of sides of the protective enclosure directs an airflow over the plurality of solar energy receivers in the X by Y array.

6. The solar energy receiver of claim 1, wherein each of the plurality of sides are configured to create a vacuum over the opening to remove particulates from the X by Y array responsive to airflow over the protective housing.

7. The solar energy receiver of claim 1, wherein each of the plurality of solar energy receivers further comprises:
a primary reflector;
a secondary reflector suspended above the primary reflector;
a housing for containing the primary reflector; and
a solar cell mounted on the face of the primary reflector for receiving energy reflected from the secondary reflector.

8. The solar energy receiver array of claim 7, wherein the primary reflector further comprises a heat sink, the primary reflector and the heat sink integrated into a single unit.

9. The solar energy receiver array of claim 7, further including a transparent cover enclosing the primary reflector within the housing, wherein the transparent cover has mounted therein the secondary reflector to suspend the secondary reflector above the primary reflector.

10. The solar energy receiver array of claim 1, further including at least one support arm for suspending the secondary reflector above the primary reflector.

11. The solar energy receiver array of claim 1, further including an inverter for converting DC electricity generated by the plurality of solar energy receivers to AC electricity.

12. The solar energy receiver array of claim 1, further including:
a transceiver for wirelessly connecting to a central controller;
wherein an orientation of the plurality of solar energy receivers may be configured by the central controller.

13. The solar energy receiver of claim 1, further including a central controller for directing electrical energy generated by the solar energy receiver array to a selected location via a power grid.

14. The solar energy receiver of claim 1, wherein each of the solar energy receivers comprises a self tracking solar energy receiver for detecting a position of a sun and aligning a pointing axis of the solar energy receiver with the sun.

15. The solar energy receiver of claim 14, further including a tracking algorithm for controlling the position of the pointing axis of the solar energy receiver.

16. The solar energy receiver of claim 14, further including:
a plurality of light sensors for sensing the position of the sun and generating control signals responsive thereto;
a controller for controlling the position of the pointing axis of the solar energy receiver responsive to the control signal.

17. The solar energy receiver of claim 16, further including:
a memory for storing historical data relating to the position of the point axis of the solar energy receiver and the position of the sun;
wherein the control further uses the historical data for controlling the position of the pointing axis of the solar energy receiver.

18. The solar energy receiver of claim 16, wherein the controller uses the historical data to adjust sensor readings of the plurality of light sensors to correct for errors in sensor reading measurements.

19. A solar energy receiver array, comprising:
a plurality of solar energy receivers arranged in an X by Y array, each of the solar energy receivers comprises a self tracking solar energy receiver for detecting a position of a sun and aligning a pointing axis of the solar energy receiver with the sun, wherein each of the plurality of solar energy receivers further comprises:
a primary reflector;
a secondary reflector suspended above the primary reflector;
a housing for containing the primary reflector;
a solar cell mounted on the face of the primary reflector for receiving energy reflected from the secondary reflector;
wherein a first edge of the X by Y array may be raised from a first position within the protective housing to a second position outside of the protective housing and further wherein the X by Y array pivots on a second edge of the X by Y array as the first edge of the X by Y array moves from the first position to the second position;
wherein each of the plurality of solar energy receivers of the X by Y array rotate about a first columnar axis;
a protective housing including a plurality of sides defining an opening therein; and
wherein the plurality of solar energy receivers arranged in the X by Y array may lowered into the opening within the protective housing to protect the plurality of solar energy receivers arranged in the X by Y from external winds.

20. The solar energy receiver array of claim 19, wherein each of the plurality of solar energy receivers of the X by Y array rotate about a second axis perpendicular to the first columnar axis.

21. The solar energy receiver array of claim 19, wherein each of the plurality of sides of the protective enclosure directs airflow over the plurality of solar energy receivers in the X by Y array.

22. The solar energy receiver of claim 19, wherein each of the plurality of sides are configured to create a vacuum over the opening to remove particulates from the X by Y array responsive to airflow over the protective housing.

23. The solar energy receiver array of claim 19, wherein the primary reflector further comprises a heat sink, the primary reflector and the heat sink integrated into a single unit.

24. The solar energy receiver array of claim 19, further including a transparent cover enclosing the primary reflector within the housing, wherein the transparent cover has mounted therein the secondary reflector to suspend the secondary reflector above the primary reflector.

25. The solar energy receiver array of claim 19, further including at least one support arm for suspending the secondary reflector above the primary reflector.

26. The solar energy receiver array of claim 19, further including an inverter for converting DC electricity generated by the plurality of solar energy receivers to AC electricity.

27. The solar energy receiver array of claim 19, further including:
a transceiver for wirelessly connecting to a central controller; and
wherein an orientation of the plurality of solar energy receivers may be configured by the central controller.

28. The solar energy receiver of claim 19, further including a central controller for directing electrical energy generated by the solar energy receiver array to a selected location via a power grid.

29. The solar energy receiver of claim 19, further including a tracking algorithm for controlling the position of the pointing axis of the solar energy receiver.

30. The solar energy receiver of claim 19, further including:
a plurality of light sensors for sensing the position of the sun and generating control signals responsive thereto;
a controller for controlling the position of the pointing axis of the solar energy receiver responsive to the control signal.

31. The solar energy receiver of claim 30, further including:
a memory for storing historical data relating to the position of the point axis of the solar energy receiver and the position of the sun;
wherein the control further uses the historical data for controlling the position of the pointing axis of the solar energy receiver.

32. The solar energy receiver of claim 30, wherein the controller uses the historical data to adjust sensor readings of the plurality of light sensors to correct for errors in sensor reading measurements.

33. The solar energy receiver of claim 19, further including:
a DC/DC converter associated with each of the plurality of solar energy receivers; and
a battery associated with each of the plurality of solar energy receivers.
